(19) United States
(12) Patent Application Publication
(10) Pub. No.: US 2025/0359416 A1
(43) Pub. Date: Nov. 20, 2025

(54) DISPLAY DEVICE AND ELECTRONIC DEVICE

(71) Applicant: Samsung Display Co., LTD., Yongin-si (KR)

(72) Inventors: Kyu Tae PARK, Yongin-si (KR); Jun Tae KIM, Yongin-si (KR); Byoung Kyoo PARK, Yongin-si (KR); Byung Jin PARK, Yongin-si (KR); Kyu Hun SHIM, Yongin-si (KR); Soo Yong YOON, Yongin-si (KR); Ga Mi LEE, Yongin-si (KR)

(21) Appl. No.: 19/043,740

(22) Filed: Feb. 3, 2025

(30) Foreign Application Priority Data
May 17, 2024 (KR) 10-2024-0064560

(51) Int. Cl. H10H 29/852; H10H 29/85

(52) U.S. Cl. CPC H10H 29/852; H10H 29/857

(57) ABSTRACT

A display device includes: a display panel including a front surface, on which a display area is define, and a rear surface opposite to the front surface; a connection layer disposed on the rear surface of the display panel; a cover disposed on the connection layer, where a hole overlapping the connection layer is defined through the cover; and a first adhesive layer disposed on the cover, where the first adhesive layer is in contact with the cover, and in contact with the connection layer through the hole of the cover, and the first adhesive layer is detachably connected to the cover and the connection layer.

This application claims priority to Korean Patent Application No. 10-2024-0064560, filed on May 17, 2024, and all the benefits accruing therefrom under 35 U.S.C. § 119, the content of which in its entirety is herein incorporated by reference.

### BACKGROUND

### 1. Field

Embodiments of the disclosure relate to a display device, and more particularly, to a display device and an electronic device that improve adhesion force and coupling force between a display panel and a cover and has easy reworkability.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices.

### SUMMARY

Embodiments of the disclosure provide a display device that improves adhesion force and coupling force between a display panel and a cover and has easy reworkability.

However, embodiments of the disclosure are not restricted to those set forth herein. The above and other features of embodiments of the disclosure will become more apparent to one of ordinary skill in the art to which the disclosure pertains by referencing the detailed description given below.

According to an embodiment of the disclosure, a display device includes: a display panel including a front surface, on which a display area is defined, and a rear surface opposite to the front surface; a connection layer disposed on the rear surface of the display panel; a cover disposed on the connection layer, where a hole overlapping the connection layer is defined through the cover; and a first adhesive layer disposed on the cover, where the first adhesive layer is in contact with the cover, and in contact with the connection layer through the hole of the cover, and the first adhesive layer is detachably connected to the cover and the connection layer.

In an embodiment, the first adhesive layer may include a detachable tape.

In an embodiment, the display device may further include a second adhesive layer disposed between the rear surface of the display panel and the connection layer.

In an embodiment, the display device may further include a third adhesive layer disposed between an edge on the rear surface of the display panel and an edge of the cover.

In an embodiment, in a plan view, the hole of the cover may surround the connection layer.

In an embodiment, the first adhesive layer may be in contact with an outer surface of the cover positioned on a left side of the hole and an outer surface of the cover positioned on a right side of the hole in a plan view.

In an embodiment, the first adhesive layer may be in contact with an outer surface of the cover positioned on an upper side of the hole and an outer surface of the cover positioned on a lower side of the hole in a plan view.

In an embodiment, the first adhesive layer may be in contact with an outer surface of the cover positioned on a left side of the hole, an outer surface of the cover positioned on a right side of the hole, an outer surface of the cover positioned on an upper side of the hole, and an outer surface of the cover positioned on a lower side of the hole.

In an embodiment, in a plan view, an edge of the first adhesive layer may surround the hole and the connection layer.

In an embodiment, an inner wall of the hole of the cover may have a curved portion.

In an embodiment, the inner wall of the hole of the cover may have the curved portion in an area in contact with the first adhesive layer.

In an embodiment, the hole of the cover may have a size which gradually decreases along a direction toward the display panel.

In an embodiment, in a plan view, an edge of the connection layer may surround the hole.

In an embodiment, the display device may further include a third adhesive layer disposed between the edge of the connection layer and an edge of the cover.

According to another embodiment of the disclosure, a display device includes: a display panel including a front surface, on which a display area is defined, and a rear surface opposite to the front surface; a connection layer disposed on the rear surface of the display panel; a cover disposed on the connection layer and including a protrusion portion overlapping the connection layer; and a magnet disposed between the connection layer and the protrusion portion of the cover, where the magnet is in contact with the protrusion portion of the cover and the connection layer, and the magnet is detachably connected to the cover and the connection layer.

In an embodiment, in a plan view, an edge of the connection layer may surround the magnet.

In an embodiment, in a plan view, an edge of the protrusion portion may surround the connection layer and the magnet.

According to another aspect of the disclosure, a display device includes: a display panel including a front surface, on which a display area is defined, and a rear surface disposed on a side opposite to the front surface; a connection layer disposed on the rear surface of the display panel; a cover disposed on the connection layer and including a protrusion portion overlapping the connection layer; and a magnet disposed on the protrusion portion of the cover to overlap the connection layer, wherein the magnet is in contact with the protrusion portion of the cover, and the magnet is detachably connected to the cover.

In an embodiment, in a plan view, an edge of the connection layer may surround the magnet.

According to another embodiment of the disclosure, a display device includes: a display panel including a front surface on which a display area is disposed and a rear surface opposite to the front surface; a connection layer disposed on the rear surface of the display panel; a cover disposed on the connection layer, where a hole overlapping the connection layer is defined through the cover; and a magnet disposed on the cover, where the magnet is in contact with the cover, and in contact with the connection layer through the hole of the cover, and the magnet is detachably connected to the cover and the connection layer.

In an embodiment, in a plan view, an edge of the magnet may surround the hole of the cover and the connection layer.

In an embodiment, the magnet and the connection layer may be in contact with each other.

In an embodiment, the magnet may include: a first member disposed on the cover; and a second member extending from the first member toward the connection layer and in contact with the connection layer within the hole of the cover.

According to another embodiment of the disclosure, a display device includes: a display panel including a front surface, on which a display area is defined, and a rear surface opposite to the front surface; a cover disposed on the rear surface of the display panel, where a hole is defined through the cover; and a connection member disposed between the display panel and the cover, where the connection member includes: a base portion disposed between the display panel and the cover; an extension portion extending from the base portion and inserted into the hole of the cover; and a fastening portion disposed on the cover to overlap the hole and connected to the extension portion.

In an embodiment, a through hole may be defined through the extension portion and the fastening portion.

In an embodiment, the display device may further include an adhesive layer disposed between the rear surface of the display panel and the base portion.

According to another embodiment of the disclosure, a display device includes: a display panel including a front surface, on which a display area is defined, and a rear surface opposite to the front surface; a cover disposed on the rear surface of the display panel, where a hole is defined through the cover; a connection layer disposed between the display panel and the cover and including a groove overlapping the hole of the cover; and a connection part disposed through the hole of the cover and inserted into the groove of the connection layer.

In an embodiment, the connection part may include: an extension portion inserted into the hole and the groove; and a head portion disposed on the cover to overlap the hole and connected to the extension portion.

According to another embodiments of the disclosure, a display device includes: a display panel including a front surface, on which a display area is defined, and a rear surface opposite to the front surface; a cover disposed on the rear surface of the display panel, where a hole is defined through the cover; a connection layer disposed between the display panel and the cover and including a plurality of flexures extending to an outside of the cover through the hole of the cover; and a connection part inserted into through holes of the plurality of flexures in a direction crossing an extension direction of the plurality of flexures.

According to another embodiment of the disclosure, a display device includes: a display panel including a front surface, on which a display area is defined, and a rear surface opposite to the front surface; a cover disposed on the rear surface of the display panel, where a hole is defined through the cover; and an adhesive member disposed on the cover to overlap the hole of the cover, where the adhesive member includes: a base layer disposed on the cover and the hole; a connection layer disposed between the rear surface of the display panel and the base layer within the hole; and an adhesive layer disposed between the rear surface of the display panel and the connection layer and between the cover and the base layer.

In an embodiment, the adhesive member may be detachably connected to the rear surface of the display panel and the cover.

According to an embodiment of the disclosure, an electronic device includes: a processor; a memory; and a display device, wherein the display device includes: a display panel including a front surface, on which a display area is defined, and a rear surface opposite to the front surface; a connection layer disposed on the rear surface of the display panel; a cover disposed on the connection layer, where a hole overlapping the connection layer is defined through the cover; and a first adhesive layer disposed on the cover, where the first adhesive layer is in contact with the cover, and in contact with the connection layer through the hole of the cover, and the first adhesive layer is detachably connected to the cover and the connection layer.

In embodiments of a display device according to the disclosure, adhesion force and coupling force between a display panel and a cover may be improved, and reworkability of the display device may be improved.

The effects of the disclosure are not limited to the above-described effects and other effects which are not described herein will become apparent to those skilled in the art from the following description.

### BRIEF DESCRIPTION OF THE DRAWINGS

The above and other features of embodiments of the disclosure will become more apparent by describing in greater detail embodiments thereof with reference to the accompanying drawings, in which:

FIG. 1 is a perspective view of a display device according to an embodiment;

FIG. 2 is a detailed configuration diagram of a display panel of FIG. 1;

FIG. 3 is a view of the display device of FIG. 1 viewed from an outer surface of a cover;

FIG. 4 is an enlarged view of area A1 of FIG. 1;

FIG. 5 is a cross-sectional view taken along line I-I′ of FIG. 3;

FIGS. 6 and 7 are views for describing a method of attaching an auxiliary adhesive layer according to an embodiment;

FIGS. 8 and 9 are views for describing a method of detaching the auxiliary adhesive layer according to an embodiment;

FIG. 10 is an enlarged view of another embodiment of area A1 of FIG. 1;

FIG. 11 is an enlarged view of another embodiment of area A1 of FIG. 1;

FIG. 12 is an enlarged view of another embodiment of area A1 of FIG. 1;

FIG. 13 is a cross-sectional view of another embodiment taken along line I-I′ of FIG. 3;

FIG. 14 is a cross-sectional view of another embodiment taken along line I-I′ of FIG. 3;

FIG. 15 is a perspective view of a display device according to an embodiment;

FIG. 16 is a view of the display device of FIG. 15 viewed from an outer surface of a cover;

FIG. 17 is an enlarged view of area A2 of FIG. 16;

FIG. 18 is a cross-sectional view taken along line II-II′ of FIG. 16;

FIG. 19 is a perspective view of a display device according to an embodiment;

FIG. 20 is a view of the display device of FIG. 19 viewed from an outer surface of a cover;

FIG. 21 is an enlarged view of area A3 of FIG. 20;

FIG. 22 is a cross-sectional view taken along line III-III′ of FIG. 20;

FIG. 23 is a perspective view of a display device according to an embodiment;

FIG. 24 is a view of the display device of FIG. 23 viewed from an outer surface of a cover;

FIG. 25 is an enlarged view of area A4 of FIG. 24;

FIG. 26 is a cross-sectional view taken along line IV-IV′ of FIG. 24;

FIG. 27 is a perspective view of a display device according to an embodiment;

FIG. 28 is a view of the display device of FIG. 27 viewed from an outer surface of a cover;

FIG. 29 is an enlarged view of area A5 of FIG. 28;

FIG. 30 is a cross-sectional view taken along line V-V′ of FIG. 28;

FIG. 31 is a perspective view of a display device according to an embodiment;

FIG. 32 is a view of the display device of FIG. 31 viewed from an outer surface of a cover;

FIG. 33 is an enlarged view of area A6 of FIG. 32;

FIG. 34 is a cross-sectional view taken along line IV-IV′ of FIG. 32;

FIG. 35 is a perspective view of a display device according to an embodiment;

FIG. 36 is a view of the display device of FIG. 35 viewed from an outer surface of a cover;

FIG. 37 is an enlarged view of area A7 of FIG. 36;

FIG. 38 is a cross-sectional view taken along line VII-VII′ of FIG. 36;

FIG. 39 is a perspective view of a display device according to an embodiment;

FIG. 40 is a view of the display device of FIG. 39 viewed from an outer surface of a cover;

FIG. 41 is an enlarged view of area A8 of FIG. 40;

FIG. 42 is a cross-sectional view taken along line VIII-VIII′ of FIG. 40;

FIG. 43 is a cross-sectional view of another embodiment taken along line VIII-VIII′ of FIG. 40;

FIG. 44 is a cross-sectional view of another embodiment taken along line VIII-VIII′ of FIG. 40;

FIG. 45 is a cross-sectional view of a display device according to an embodiment;

FIG. 46 is a cross-sectional view of a display device according to an embodiment;

FIG. 47 is a cross-sectional view of a display device according to an embodiment;

FIG. 48 is a cross-sectional view of a display device according to an embodiment; and

FIG. 49 is a view illustrating a form in which an adhesive member of FIG. 48 is attached to a cover and a display panel.

FIG. 50 is a block diagram of an electronic device according to one embodiment.

FIGS. 51, 52 and 53 are schematic diagrams of electronic devices according to various embodiments.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will also be understood that when a layer is referred to as being “on” another layer or substrate, it can be directly on the other layer or substrate, or intervening layers may also be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Features of various embodiments of the disclosure may be combined partially or totally. As will be clearly appreciated by those skilled in the art, technically various interactions and operations are possible. Various embodiments can be practiced individually or in combination.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

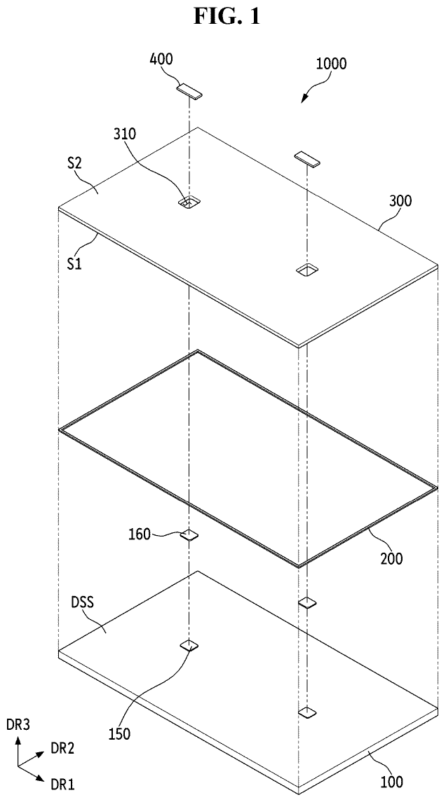

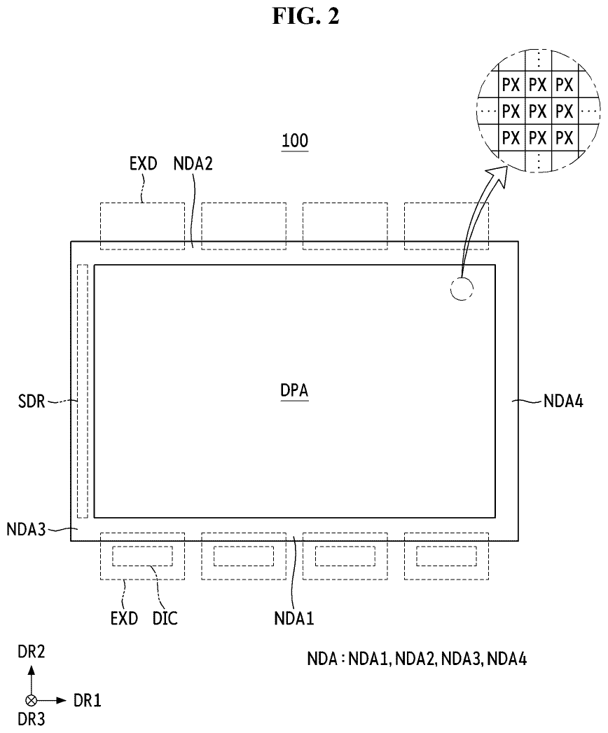

FIG. 1 is a perspective view of a display device 1000 according to an embodiment, and FIG. 2 is a detailed configuration diagram of a display panel 100 of FIG. 1.

The display device 1000 according to an embodiment may include a display panel 100, a connection layer 160, a cover 300, a first adhesive layer 400 (hereinafter referred to as an auxiliary adhesive layer 400), a second adhesive layer 150 (hereinafter referred to as an intermediate adhesive layer 150), and a third adhesive layer 200 (hereinafter referred to as an outer adhesive layer 200), as illustrated in FIG. 1.

The display panel 100 may display an image. The display panel 100 may have a square shape in a plan view (or when viewed in a third direction DR3), as illustrated in FIG. 2. In an embodiment, for example, the display panel 100 may have a rectangular shape, but is not limited thereto.

The display panel 100 may include a display area DPA and a non-display area NDA. The display area DPA may be an active area where an image is displayed. The display area DPA may have a rectangular shape in a plan view, similar to the overall shape of the display device 100, but is not limited thereto.

A plurality of pixels PX may be disposed in the display area DPA. The plurality of pixels PX may be arranged in a matrix form. A shape of each pixel PX may be a rectangular shape or a square shape in a plan view, but is not limited thereto, and may also be a rhombic shape, each side of which is inclined with respect to one side direction of the display panel 100. The plurality of pixels PX may provide light of several colors. In an embodiment, for example, the plurality of pixels PX may include, but are not limited to, a first pixel providing red light, a second pixel providing green light, and a third pixel providing blue light. The first, second, and third pixels may be alternately arranged in a stripe type or Pentile type.

The non-display area NDA may be disposed around the display area DPA. The non-display areas NDA may constitute a bezel of the display panel 100. The non-display area NDA may entirely or partially surround the display area DPA.

In some embodiments, the display area DPA may have a rectangular shape, and the non-display area NDA may be disposed adjacent to four sides of the display area DPA. The display panel 100 may have a long side extending in a first direction DR1 and a short side extending in a second direction DR2 crossing the first direction DR1. Here, the third direction DR3 or the thickness direction of the display panel 100 may be a direction perpendicular to a plane defined by the first direction DR1 and the second direction DR2. In an embodiment, for example, the non-display area NDA may include a first non-display area NDA1 disposed adjacent to a first long side (lower side in FIG. 2) of the display panel 100, a second non-display area NDA2 disposed adjacent to a second long side (upper side in FIG. 2) of the display panel 100, a third non-display area NDA3 disposed adjacent to a first short side (left side in FIG. 2) of the display panel 100, and a fourth non-display area NDA4 disposed adjacent to a second short side (right side in FIG. 2) of the display panel 100.

Driving circuits or driving elements driving the display area DPA may be disposed in the non-display area NDA. In an embodiment, for example, pad portions may be provided in the first non-display area NDA1 and the second non-display area NDA2, and external devices EXD may be mounted on pad electrodes of the pad portions. The external device EXD may include a circuit member. The circuit member may include, for example, a connection film, a printed circuit board, a driving chip DIC, a connector, a line connection film, or the like. The driving chip DIC may, for example, drive a plurality of data lines disposed on the display panel 100. In another embodiment, for example, a scan driver SDR or the like may be disposed in the third non-display area NDA3. In an embodiment, for example, the scan driver may drive a plurality of scan lines disposed on the display panel 100. The plurality of pixels described above may be connected to the data lines and the scan lines.

The outer adhesive layer 200 and the intermediate adhesive layer 150 may be disposed on the display panel 100. In an embodiment, for example, the display panel 100 may include a front surface on which the display area DPA described above is disposed and a rear surface DSS disposed on a side opposite to the front surface, and the outer adhesive layer 200 and the intermediate adhesive layer 150 described above may be disposed on the rear surface DSS of the display panel 100.

The outer adhesive layer 200 may be disposed at an edge of the display panel 100. In an embodiment, for example, the outer adhesive layer 200 may be disposed on the rear surface DSS of the display panel 100 along an edge of the rear surface DSS. In an embodiment, the outer adhesive layer 200 may have a shape of a closed curve or a frame surrounding the edge of the display panel 100. One surface of the outer adhesive layer 200 may be in contact with the rear surface DSS of the display panel 100. In an embodiment, for example, one surface of the outer adhesive layer 200 may be attached to the rear surface DSS of the display panel 100. The outer adhesive layer 200 may include a double-sided tape.

The intermediate adhesive layer 150 may be disposed on the rear surface DSS of the display panel 100 to be surrounded by the outer adhesive layer 200 in a plan view or when viewed in the third direction DR3. One surface of the intermediate adhesive layer 150 may be in contact with the rear surface DSS of the display panel 100. In an embodiment, for example, one surface of the intermediate adhesive layer 150 may be attached to the rear surface DSS of the display panel 100. The intermediate adhesive layer 150 may include a double-sided tape.

The connection layer 160 may be disposed on (or to overlap) the intermediate adhesive layer 150. The connection layer 160 may be in contact with the intermediate adhesive layer 150. In an embodiment, for example, the connection layer 160 may be attached to an opposing surface (i.e., the surface opposite to the one surface) of the intermediate adhesive layer 150. In a plan view, the connection layer 160 may be surrounded by the outer adhesive layer 200 described above.

The connection layer 160 may include a metal. In an embodiment, for example, the connection layer 160 may include or be made of a material including at least one selected from stainless steel, aluminum (Al), copper (Cu), and graphite. The connection layer 160 may function as a heat sink.

The cover 300 may be disposed on the connection layer 160 and the outer adhesive layer 200. In an embodiment, for example, the cover 300 may be disposed on the connection layer 160 and the outer adhesive layer 200 to cover (or overlap) the rear surface DSS of the display panel 100. The cover 300 may protect the display panel 100 from an external shock or the like. The cover 300 may include a metal material. The cover 300 may have a same shape as the display panel 100. In an embodiment, for example, the cover 300 may have a rectangular shape in a plan view, similar to the overall shape of the display panel 100, but is not limited thereto.

The outer adhesive layer 200 described above may be disposed between the edge of the display panel 100 and an edge of the cover 300, and the edge of the cover 300 may be in contact with an opposing surface of the outer adhesive layer 200. In an embodiment, for example, the edge of the cover 300 may be attached to the opposing surface of the outer adhesive layer 200. The edge of the display panel 100 and the edge of the cover 300 may be attached to each other by the outer adhesive layer 200.

The cover 300 may be provided with a hole 310, that is, the hole 310 is defined or formed through the cover 300. The hole 310 may be defined or formed through the cover 300 in a thickness direction of the cover 300 (e.g., the third direction DR3). The hole 310 may overlap the connection layer 160. In an embodiment, for example, in a plan view, the connection layer 160 may be surrounded by the hole 310. In an embodiment, in a plan view, the intermediate adhesive layer 150 may be surrounded by the hole 310. At least a portion of the connection layer 160 may be exposed to the outside of the cover 300 through the hole 310. In addition, in a plan view, the hole 310 may be surrounded by the outer adhesive layer 200 described above. The hole 310 may have a quadrangular shape, but is not limited thereto. In an embodiment, for example, the hole 310 may have a shape such as a circular shape or a triangular shape. In addition, the hole 310 may have a polygonal shape with round corners.

The auxiliary adhesive layer 400 may be disposed on the cover 300. The auxiliary adhesive layer 400 may be disposed on the cover 300 to overlap the hole 310 of the cover 300. One surface of the auxiliary adhesive layer 400 may be in contact with the cover 300 and the connection layer 160. In an embodiment, for example, one surface of the auxiliary adhesive layer 400 may be attached to the cover 300 and the connection layer 160. In such an embodiment, the auxiliary adhesive layer 400 may be attached to the connection layer 160 through the hole 310 of the cover 300. The auxiliary adhesive layer 400 may include, for example, a tape. In such an embodiment, the auxiliary adhesive layer 400 includes an adhesive material on one surface thereof, and may include a bendable tape. According to an embodiment, the auxiliary adhesive layer 400 may be detachably connected to (or in contact with or attached to) the cover 300 and the connection layer 160.

Both opposing surfaces of the cover 300, which are opposite to each other in the third direction DR3, may be defined as an inner surface S1 and an outer surface S2 of the cover 300, respectively, and the inner surface S1 of the cover 300 may face the rear DSS of the display panel 100.

The inner surface S1 of the cover 300 described above and the rear surface DSS of the display panel 100 may be attached to each other through the outer adhesive layer 200.

The outer surface S2 of the cover 300 described above and the rear surface DSS of the display panel 100 may be attached to each other through the auxiliary adhesive layer 400. In an embodiment, for example, the auxiliary adhesive layer 400 may be not only directly attached to the outer surface S2 of the cover 300, but also indirectly attached to the rear surface DSS of the display panel 100 through the connection layer 160 exposed by the hole 310 of the cover 300 and the intermediate adhesive layer 150 adhering the connection layer 160 and the rear surface DSS of the display panel 100 to each other. Accordingly, adhesion force and coupling force between the cover 300 and the display panel 100 may be further improved by such an auxiliary adhesive layer 400. Therefore, a phenomenon in which a central portion of the cover 300 is lifted from the display panel 100 may be effectively prevented, and a heat dissipation effect through the cover 300 may also be improved.

According to an embodiment, adhesive strength of the intermediate adhesive layer 150 and adhesive strength of the auxiliary adhesive layer 400 may be different from each other. In an embodiment, for example, the adhesive strength of the intermediate adhesive layer 150 may be greater than the adhesive strength of the auxiliary adhesive layer 400.

The display device 1000 according to an embodiment, as illustrated in FIG. 1, may include two intermediate adhesive layers 150, two connection layers 160, two holes 310, and two auxiliary adhesive layers 400. Here, any one of the two intermediate adhesive layers 150, any one of the two connection layers 160, any one of the two holes 310, and any one of the two auxiliary adhesive layers 400 may be disposed adjacent to one side of the display panel 100, and the other of the two intermediate adhesive layers 150, the other of the two connection layers 160, the other of the two holes 310, and the other of the two auxiliary adhesive layers 400 may be disposed adjacent to an opposing side (i.e., the side opposite to the one side of) of the display panel 100. In such an embodiment, the one side and the opposing side of the display panel 100 may be sides opposite to each other in the first direction DR1, for example.

However, the numbers of components (e.g., intermediate adhesive layers 150, connection layers 160, holes 310, and auxiliary adhesive layers 400) described above are not limited thereto, and may be variously modified. In another embodiment, for example, the display device 1000 may include four intermediate adhesive layers 150 disposed on the rear surface DSS of the display panel 100. In such an embodiment, the four intermediate adhesive layers 150 may be disposed on the rear surface DSS of the display panel 100 to respectively correspond to four corners of the display panel 100.

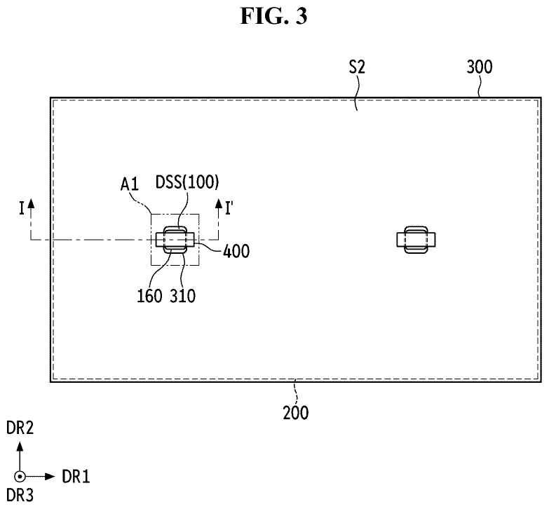

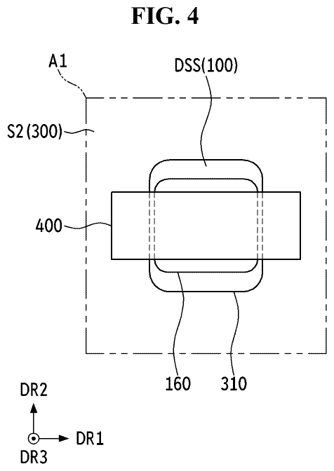

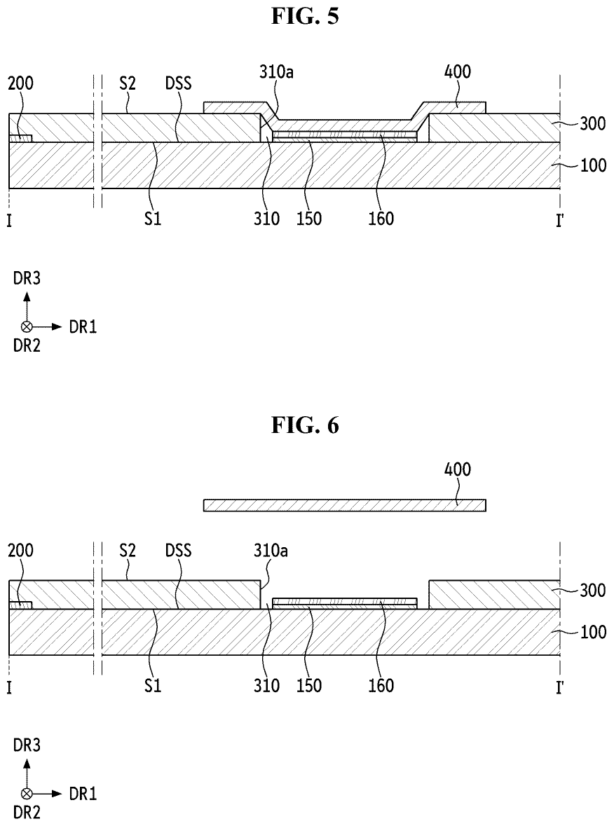

FIG. 3 is a view of the display device 1000 of FIG. 1 viewed from an outer surface S2 of a cover 300, FIG. 4 is an enlarged view of area A1 of FIG. 1, and FIG. 5 is a cross-sectional view taken along line I-I′ of FIG. 3.

In an embodiment, as illustrated in FIGS. 3 and 4, the auxiliary adhesive layer 400 may have a rectangular shape extending along the first direction DR1. The auxiliary adhesive layer 400 may be not only attached to each of the outer surface S2 of the cover 300 disposed on the left side of the hole 310 and the outer surface S2 of the cover 300 disposed on the right side of the hole 310, but also attached to the connection layer 160 through the hole 310.

In an embodiment, as illustrated in FIGS. 3 and 4, in a plan view, a size of the hole 310 may be greater than a size of the connection layer 160. In addition, in a plan view, the hole 310 may surround the connection layer 160.

In an embodiment, as illustrated in FIG. 5, the auxiliary adhesive layer 400 may be disposed on the outer surface S2 of the cover 300 and the connection layer 160. In such an embodiment where the auxiliary adhesive layer 400 is attached to the outer surface S2 of the cover 300 and the connection layer 160, the auxiliary adhesive layer 400 may be bent between the cover 300 and the connection layer 160 by a step (e.g., a height difference) between the cover 300 and the connection layer 160. The auxiliary adhesive layer 400 may be in contact with each of the outer surface S2 of the cover 300 and the connection layer 160.

In an embodiment, as illustrated in FIG. 5, an angle between an inner wall 310a of the hole 310 and the outer surface S2 of the cover 300 may be about 90°.

In an embodiment, as illustrated in FIG. 5, the outer adhesive layer 200 may be disposed between an edge of the inner surface S1 of the cover 300 and the edge of the rear surface DSS of the display panel 100.

In an embodiment, as illustrated in FIG. 4, in a plan view, each of four corners of the hole 310 may have a round shape.

In an embodiment, as illustrated in FIG. 4, in a plan view, each of four corners of the connection layer 160 may have a round shape. In an embodiment, as illustrated in FIG. 1, in a plan view, each of four corners of the intermediate adhesive layer 150 may have a round shape.

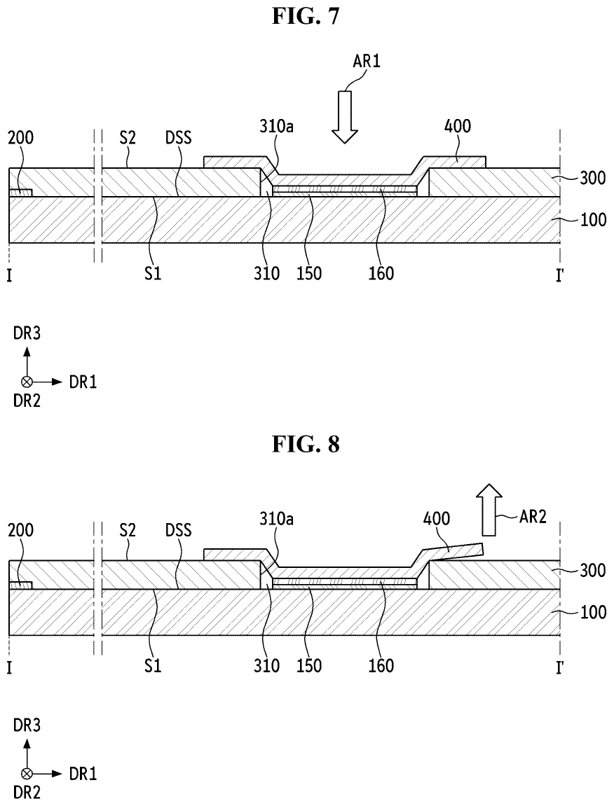

FIGS. 6 and 7 are views for describing a method of attaching an auxiliary adhesive layer 400 according to an embodiment.

In an embodiment of the method of attaching the auxiliary adhesive layer 400, as illustrated in FIG. 6, the auxiliary adhesive layer 400 may be disposed on the connection layer 160 attached to the rear surface DSS of the display panel 100 by the intermediate adhesive layer 150. In an embodiment, for example, the auxiliary adhesive layer 400 may be disposed on the hole 310 of the cover 300 to overlap the hole 310 of the cover 300.

Subsequently, as illustrated in FIG. 7, pressure may be applied to the auxiliary adhesive layer 400 in a direction of a first arrow AR1 (e.g., a direction reverse to the third direction DR3 (hereinafter referred to as a third reverse direction)). In an embodiment, for example, a worker may manually attach the auxiliary adhesive layer 400 to the outer surface S2 of the cover 300. In such an embodiment, the auxiliary adhesive layer 400 may be attached to the outer surface S2 of the cover 300 and the connection layer 160.

As described above, according to an embodiment, the auxiliary adhesive layer 400 is attached outside the cover 300, and thus, the cover 300 and the display panel 100 may be adhered to each other by a simple method.

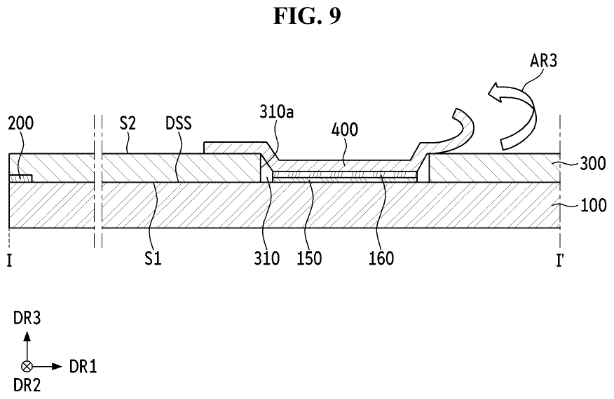

FIGS. 8 and 9 are views for describing a method of detaching the auxiliary adhesive layer 400 according to an embodiment.

In an embodiment, for example, for the purpose of reworking of the display device 1000, the cover 300 and the display panel 100 may be detached from each other. To rework the display device, the auxiliary adhesive layer 400 attached to the outer surface S2 of the cover 300 and the connection layer 160 is desired to be removed.

In an embodiment of the method of detaching the auxiliary adhesive layer 400, as illustrated in FIG. 8, the auxiliary adhesive layer 400 attached to the outer surface S2 of the cover 300 may be lifted in a direction of a second arrow AR2 (for example, the third direction DR3). In an embodiment, for example, the worker may manually pull one end of the auxiliary adhesive layer 400 in the direction of the second arrow AR2 in a state in which he/she grips one end of the auxiliary adhesive layer 400.

Thereafter, as illustrated in FIG. 9, the auxiliary adhesive layer 400 is pulled in a direction of a third arrow AR3, such that the auxiliary adhesive layer 400 may be easily detached from the cover 300 and the connection layer 160.

As described above, according to an embodiment, the auxiliary adhesive layer 400 may be easily detached from the cover 300 and the connection layer 160 by a simple method. In such an embodiment, the auxiliary adhesive layer 400 may be detachably connected to (or in contact with or attached to) the cover 300 and the connection layer 160. Accordingly, according to an embodiment, reworkability of the display device 1000 may be improved.

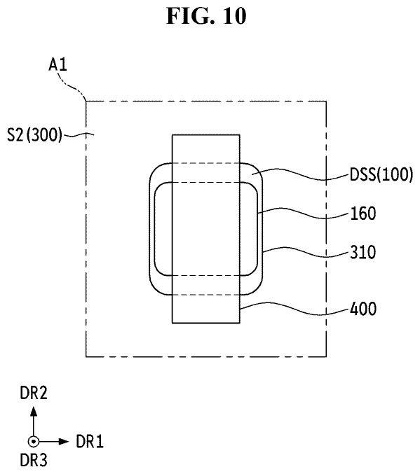

FIG. 10 is an enlarged view of another embodiment of area A1 of FIG. 1.

A display device 1000 illustrated in FIG. 10 is substantially the same as the display device 1000 described above with reference to FIG. 4 except for a shape of the auxiliary adhesive layer 400, and such a difference will be mainly described below.

In an embodiment, as illustrated in FIG. 10, the auxiliary adhesive layer 400 may have a rectangular shape extending in the second direction DR2. In such an embodiment, the auxiliary adhesive layer 400 may be not only attached to each of the outer surface S2 of the cover 300 disposed on the upper side of the hole 310 and the outer surface S2 of the cover 300 disposed on the lower side of the hole 310, but also attached to the connection layer 160 through the hole 310.

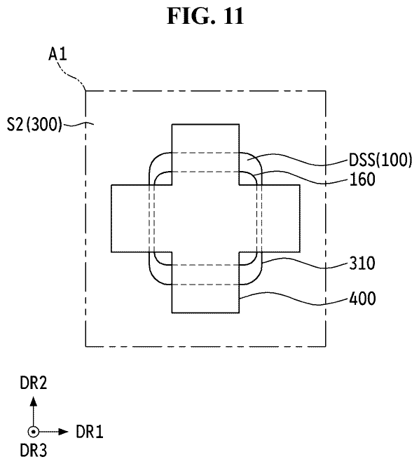

FIG. 11 is an enlarged view of another embodiment of area A1 of FIG. 1.

A display device 1000 illustrated in FIG. 11 is substantially the same as the display device 1000 described above with reference to FIG. 4 except for a shape of the auxiliary adhesive layer 400, and such a difference will be mainly described below.

In an embodiment, as illustrated in FIG. 11, the auxiliary adhesive layer 400 may have a cross shape extending in the first direction DR1 and the second direction DR2. In such an embodiment, the auxiliary adhesive layer 400 may be not only attached to each of the outer surface S2 of the cover 300 disposed on the left side of the hole 310, the outer surface S2 of the cover 300 disposed on the right side of the hole 310, the outer surface S2 of the cover 300 disposed on the upper side of the hole 310, and the outer surface S2 of the cover 300 disposed on the lower side of the hole 310, but also attached to the connection layer 160 through the hole 310.

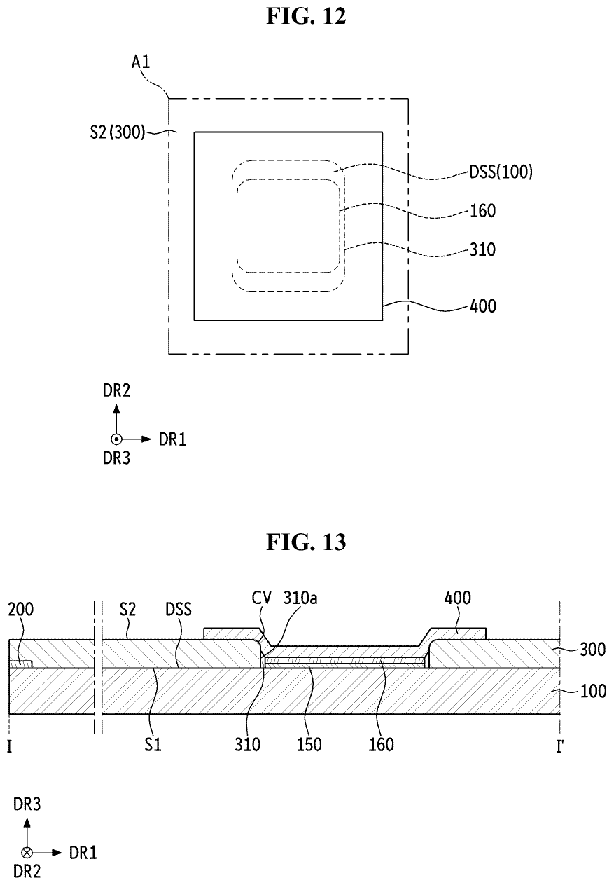

FIG. 12 is an enlarged view of another embodiment of area A1 of FIG. 1.

A display device 1000 illustrated in FIG. 12 is substantially the same as the display device 1000 described above with reference to FIG. 4 except for a shape of the auxiliary adhesive layer 400, and such a difference will be mainly described below.

As illustrated in FIG. 12, the auxiliary adhesive layer 400 may have a greater size than the hole 310 of the cover 300, the connection layer 160, and the intermediate adhesive layer 150. In an embodiment, for example, in a plan view, an edge of the auxiliary adhesive layer 400 may surround the hole 310, the connection layer 160, and the intermediate adhesive layer 150.

FIG. 13 is a cross-sectional view of another embodiment taken along line I-I′ of FIG. 3.

A display device 1000 of FIG. 13 is substantially the same as the display device 1000 described above with reference to FIG. 5 except for a shape of the inner wall 310a of the hole 310 of the cover 300, and such a difference will be described in detail below.

As illustrated in FIG. 13, in cross section, at least a portion of the inner wall 310a of the hole 310 may include a curved portion CV having a round shape. In an embodiment, for example, the inner wall 310a of the hole 310 may have the curved portion CV in an area in contact with the auxiliary adhesive layer 400. In other words, a portion where the inner wall 310a of the hole 310 and the outer surface S2 of the cover 300 are connected to each other may have a round shape. A portion of the inner wall 310a of the hole 310 has the curved portion CV, and accordingly, damage to the auxiliary adhesive layer 400 in contact with a corner portion of the inner wall 310a of the hole 310 may be effectively prevented or substantially reduced.

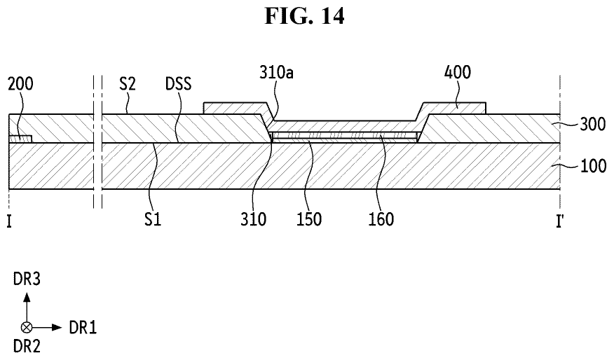

FIG. 14 is a cross-sectional view of another embodiment taken along line I-I′ of FIG. 3.

A display device 1000 of FIG. 14 is substantially the same as the display device 1000 described above with reference to FIG. 5 except for a shape of the inner wall 310a of the hole 310 of the cover 300, and such a difference will be described in detail below.

In an embodiment, as illustrated in FIG. 14, in cross section, the inner wall 310a of the hole 310 may have an inclined surface inclined in an oblique line form with respect to the outer surface S2 of the cover 300. In an embodiment, for example, the hole 310 may have a size that gradually decreases along a direction toward the display panel 100 (e.g., the third reverse direction). In other words, in cross section, a distance between inner walls 310a of the hole 310 that oppose each other may gradually decrease along the third reverse direction described above.

As the inner wall 310a of the hole 310 has the inclined surface with the oblique line form, a contact area between the inner wall 310a of the hole 310 and the auxiliary adhesive layer 400 increases, such that adhesive strength of the auxiliary adhesive layer 400 may be improved. In addition, as the inner wall 310a of the hole 310 has the inclined surface with the oblique line form, the auxiliary adhesive layer 400 may be supported by the inner wall 310a of the hole 310 in a bent area of the auxiliary adhesive layer 400. Therefore, stress applied to the auxiliary adhesive layer 400 in the bent area of the auxiliary adhesive layer 400 may be substantially reduced, such that a lifespan of the auxiliary adhesive layer 400 may be improved.

In another embodiment, a portion (e.g., a corner portion) where the inner wall 310a of the hole 310 having the oblique line form of FIG. 14 and the outer surface S2 of the cover 300 are connected to each other may have a round shape as illustrated in FIG. 13. In such an embodiment, the inner wall 310a of the hole 310 in FIG. 14 may further include the curved portion CV described above in the corner area.

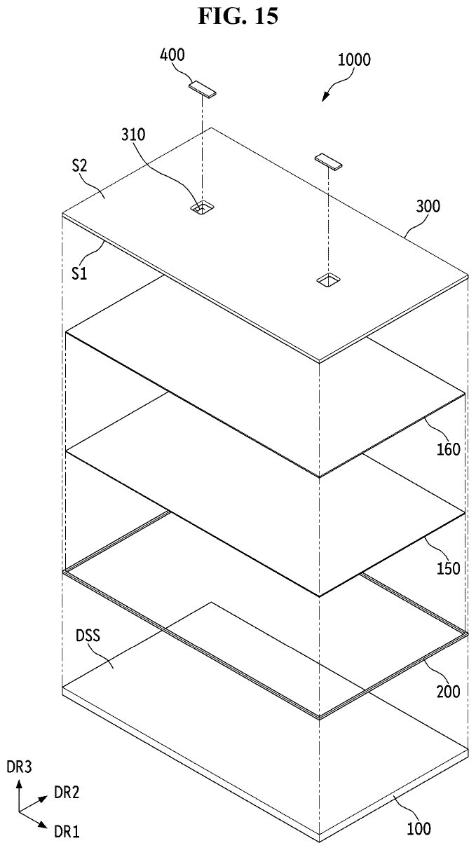

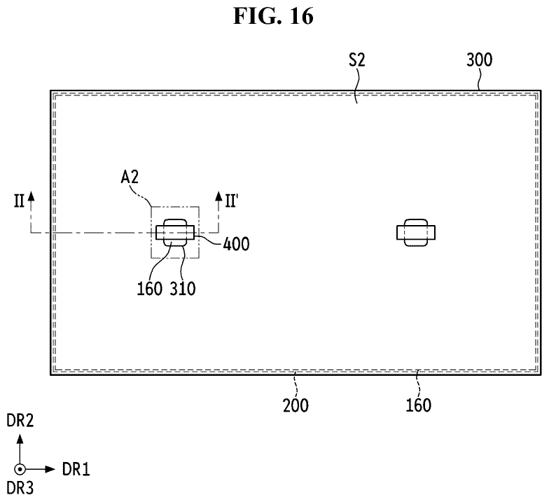

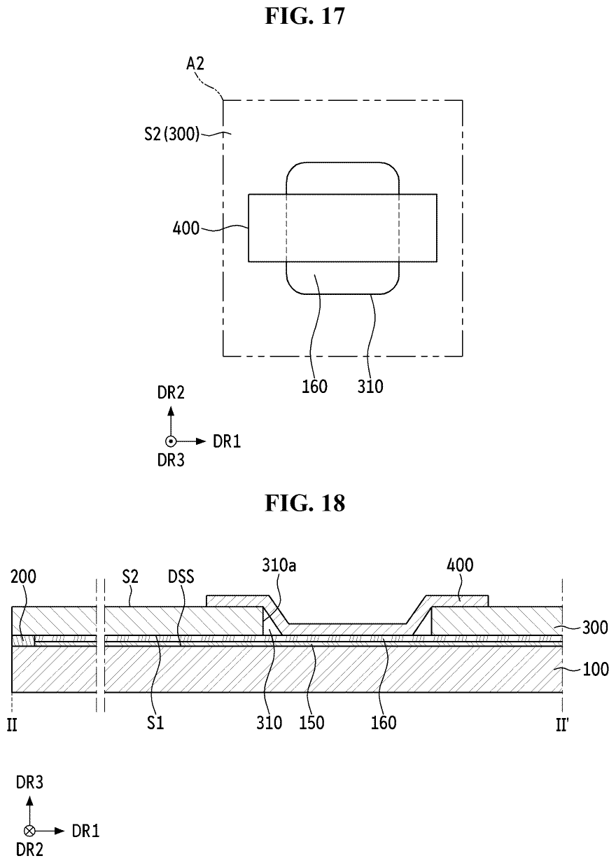

FIG. 15 is a perspective view of a display device 1000 according to an embodiment, FIG. 16 is a view of the display device 1000 of FIG. 15 viewed from an outer surface S2 of a cover 300, FIG. 17 is an enlarged view of area A2 of FIG. 16, and FIG. 18 is a cross-sectional view taken along line II-II′ of FIG. 16.

The display device 1000 of FIGS. 15 to 18 is substantially the same as the display device 1000 described above with reference to FIG. 1 except for shapes of the intermediate adhesive layer 150 and the connection layer 160, and such differences will be mainly described below.

In an embodiment, as illustrated in FIGS. 15 to 18, in a plan view, a size of the intermediate adhesive layer 150 may be greater than a size of the hole 310 of the cover 300. In an embodiment, for example, in a plan view, an edge of the intermediate adhesive layer 150 may surround the hole 310. In an embodiment, where the cover 300 of the display device 1000 is provided with a plurality of holes 310, in a plan view, the edge of the intermediate adhesive layer 150 may surround all of the plurality of holes 310.

In a plan view, the size of the intermediate adhesive layer 150 may be greater than a size of the auxiliary adhesive layer 400. In an embodiment, for example, in a plan view, the edge of the intermediate adhesive layer 150 may surround the auxiliary adhesive layer 400. In an embodiment, where the display device 1000 includes a plurality of auxiliary adhesive layers 400, in a plan view, the edge of the intermediate adhesive layer 150 may surround all of the plurality of auxiliary adhesive layers 400.

In a plan view, a size of the connection layer 160 may be greater than the size of the hole 310 of the cover 300. In an embodiment, for example, in a plan view, an edge of the connection layer 160 may surround the hole 310. In an embodiment, where the cover 300 of the display device 1000 is provided with the plurality of holes 310, in a plan view, the edge of the connection layer 160 may surround all of the plurality of holes 310.

In a plan view, the size of the connection layer 160 may be greater than the size of the auxiliary adhesive layer 400. In an embodiment, for example, in a plan view, the edge of the connection layer 160 may surround the auxiliary adhesive layer 400. In an embodiment, where the display device 1000 includes the plurality of auxiliary adhesive layers 400, in a plan view, the edge of the connection layer 160 may surround all of the plurality of auxiliary adhesive layers 400.

In a plan view, the size of the connection layer 160 may be the same as the size of the intermediate adhesive layer 150. The connection layer 160 may be disposed between the intermediate adhesive layer 150 and the cover 300.

In a plan view, the intermediate adhesive layer 150 and the connection layer 160 may be surrounded by the outer adhesive layer 200.

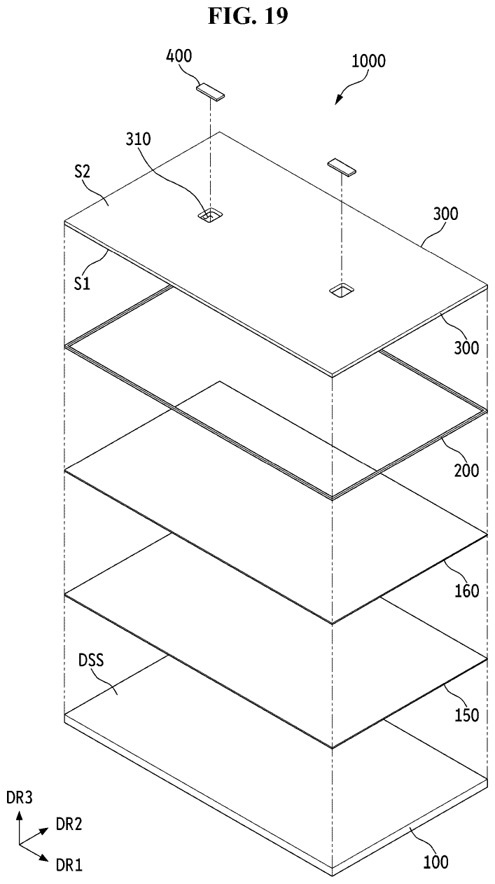

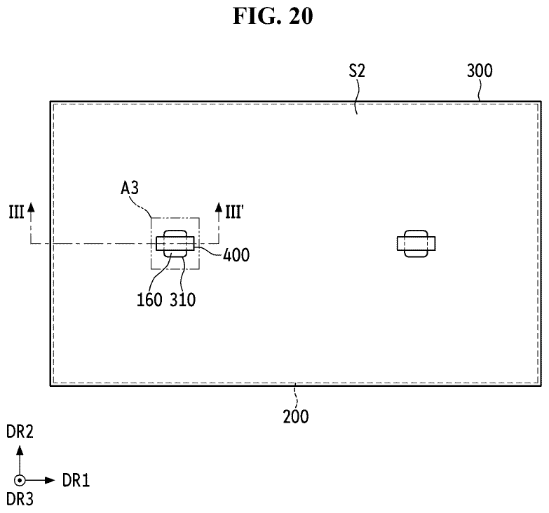

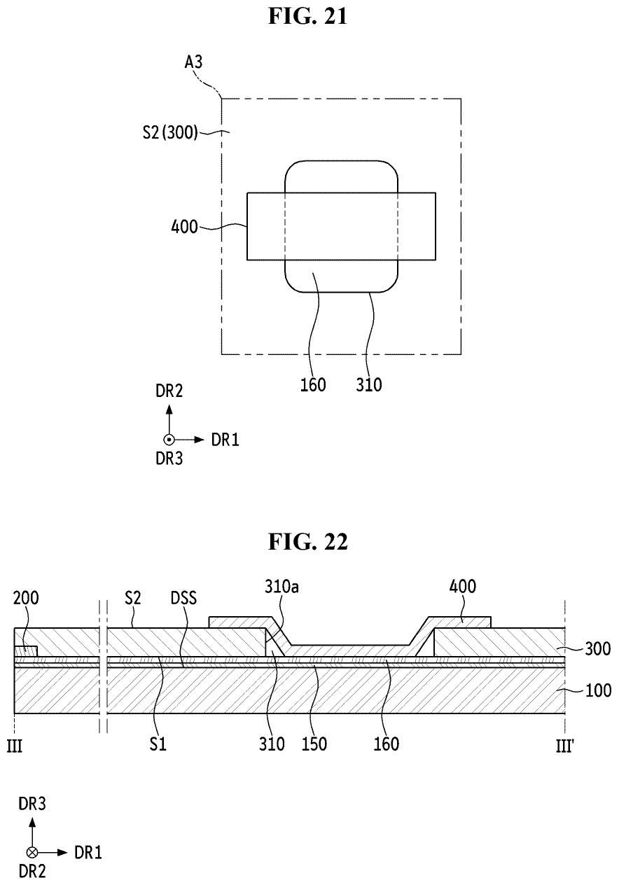

FIG. 19 is a perspective view of a display device 1000 according to an embodiment, FIG. 20 is a view of the display device 1000 of FIG. 19 viewed from an outer surface S2 of a cover 300, FIG. 21 is an enlarged view of area A3 of FIG. 20, and FIG. 22 is a cross-sectional view taken along line III-III′ of FIG. 20.

The display device 1000 of FIGS. 19 to 22 is substantially the same as the display device 1000 described above with reference to FIG. 1 except for a shape of the intermediate adhesive layer 150, a shape of the connection layer 160, and a position of the intermediate adhesive layer 150, and such differences will be mainly described below.

In an embodiment, as illustrated in FIGS. 19 to 22, in a plan view, a size of the intermediate adhesive layer 150 may be greater than a size of the hole 310 of the cover 300. In an embodiment, for example, in a plan view, an edge of the intermediate adhesive layer 150 may surround the hole 310. In an embodiment, where the cover 300 of the display device 1000 is provided with a plurality of holes 310, in a plan view, the edge of the intermediate adhesive layer 150 may surround all of the plurality of holes 310.

In a plan view, the size of the intermediate adhesive layer 150 may be greater than a size of the auxiliary adhesive layer 400. In an embodiment, for example, in a plan view, the edge of the intermediate adhesive layer 150 may surround the auxiliary adhesive layer 400. In an embodiment, where the display device 1000 includes a plurality of auxiliary adhesive layers 400, in a plan view, the edge of the intermediate adhesive layer 150 may surround all of the plurality of auxiliary adhesive layers 400.

In a plan view, a size of the connection layer 160 may be greater than the size of the hole 310 of the cover 300. In an embodiment, for example, in a plan view, an edge of the connection layer 160 may surround the hole 310. In an embodiment, where the cover 300 of the display device 1000 is provided with the plurality of holes 310, in a plan view, the edge of the connection layer 160 may surround all of the plurality of holes 310.

In a plan view, the size of the connection layer 160 may be greater than the size of the auxiliary adhesive layer 400. In an embodiment, for example, in a plan view, the edge of the connection layer 160 may surround the auxiliary adhesive layer 400. In an embodiment, where the display device 1000 includes the plurality of auxiliary adhesive layers 400, in a plan view, the edge of the connection layer 160 may surround all of the plurality of auxiliary adhesive layers 400.

In a plan view, the size of the connection layer 160 may be the same as the size of the intermediate adhesive layer 150, for example. The connection layer 160 may be disposed between the intermediate adhesive layer 150 and the outer adhesive layer 200.

In a plan view, the size of the intermediate adhesive layer 150 may be the same as a size of the display panel 100, for example.

In a plan view, the size of the connection layer 160 may be the same as the size of the display panel 100, for example.

The outer adhesive layer 200 may be disposed between the connection layer 160 and the cover 300. In an embodiment, for example, the outer adhesive layer 200 may be disposed between the edge of the connection layer 160 and an edge of the cover 300. One surface of the outer adhesive layer 200 may be in contact with the edge of the connection layer 160, and an opposing surface of the outer adhesive layer 200 may be in contact with the edge of the cover 300. The outer adhesive layer 200 may attach the connection layer 160 and the cover 300 to each other.

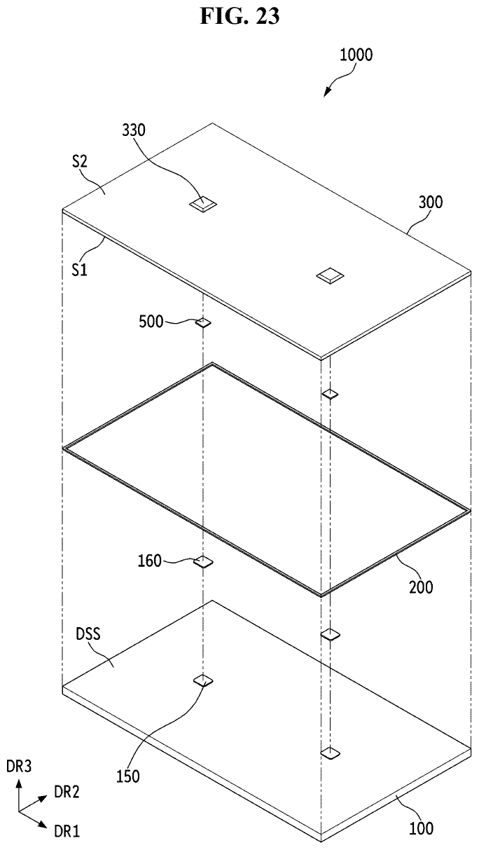

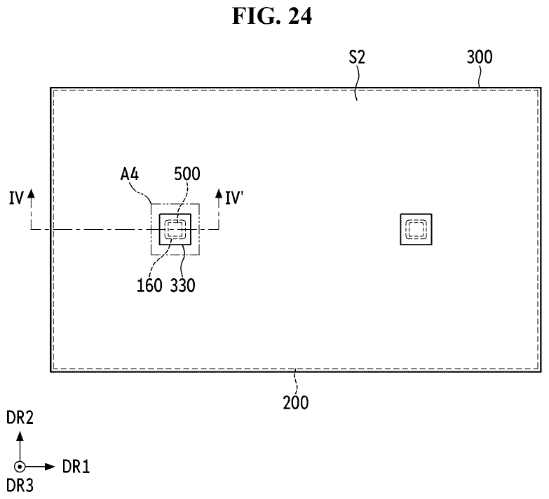

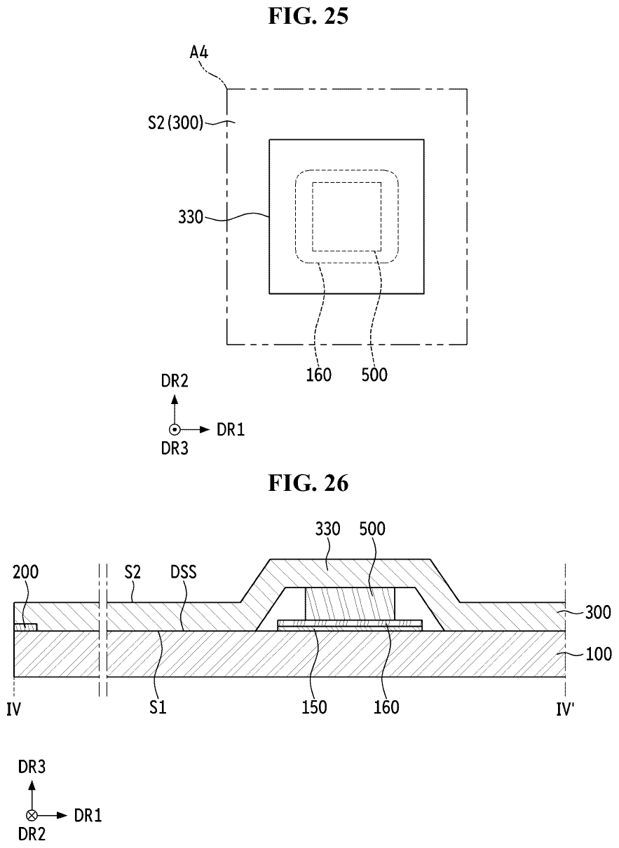

FIG. 23 is a perspective view of a display device 1000 according to an embodiment, FIG. 24 is a view of the display device 1000 of FIG. 23 viewed from an outer surface S2 of a cover 300, FIG. 25 is an enlarged view of area A4 of FIG. 24, and FIG. 26 is a cross-sectional view taken along line IV-IV′ of FIG. 24.

The display device 1000 of FIGS. 23 to 26 is substantially the same as the display device 1000 described above with reference to FIG. 1 except for a shape of the cover 300 and a magnet 500, and such differences will be mainly described below.

In an embodiment, as illustrated in FIGS. 23 to 26, the magnet 500 may be disposed between the connection layer 160 and the cover 300. The magnet 500 may overlap the connection layer 160 and the cover 300. One surface of the magnet 500 may be in contact with the connection layer 160, and an opposing surface of the magnet 500 may be in contact with the cover 300. In an embodiment, for example, the one surface of the magnet 500 may be attached to the connection layer 160 by magnetic force from the magnet 500, and the opposing surface of the magnet 500 may be attached to the cover 300 by the magnetic force from the magnet 500. The connection layer 160 and the cover 300 may be attached to each other by the magnet 500 (or the magnetic force provided from the magnet 500). In an embodiment, for example, the cover 300 may be pulled toward the connection layer 160 by the magnet 500. Accordingly, adhesion force and coupling force between the cover 300 and the display panel 100 may be improved. Here, the connection layer 160 and the cover 300 may each include a metal material. According to an embodiment, the magnet 500 may be detachably connected to (or in contact with or attached to) the cover 300 and the connection layer 160.

In an embodiment, as illustrated in FIGS. 23 and 24, in a plan view, the magnet 500 may be surrounded by the outer adhesive layer 200.

In an embodiment, as illustrated in FIG. 25, in a plan view, a size of the connection layer 160 may be greater than a size of the magnet 500. In an embodiment, for example, in a plan view, the magnet 500 may be surrounded by an edge of the connection layer 160.

The cover 300 may include a protrusion portion 330. In an embodiment, for example, a portion of the cover 300 facing the magnet 500 described above may protrude upwardly along a direction from the inner surface S1 of the cover 300 to the outer surface S2 of the cover 300 (e.g., the third direction DR3). Accordingly, the cover 300 may be disposed higher in the third direction DR3 in an area where the protrusion portion 330 is disposed than in an area where the protrusion portion 330 is not disposed. In other words, the cover 300 may be disposed higher in the third direction DR3 in an area where it overlaps the magnet 500 than in an area where it does not overlap the magnet 500.

In an embodiment, as illustrated in FIG. 26, the magnet 500 may be disposed between the connection layer 160 and the protrusion portion 330 of the cover 300. In this case, the magnet 500, the connection layer 160, and the intermediate adhesive layer 150 may be disposed in an area surrounded by the protrusion portion 330 (for example, a protrusion portion 330 having a U shape) and the display panel 100.

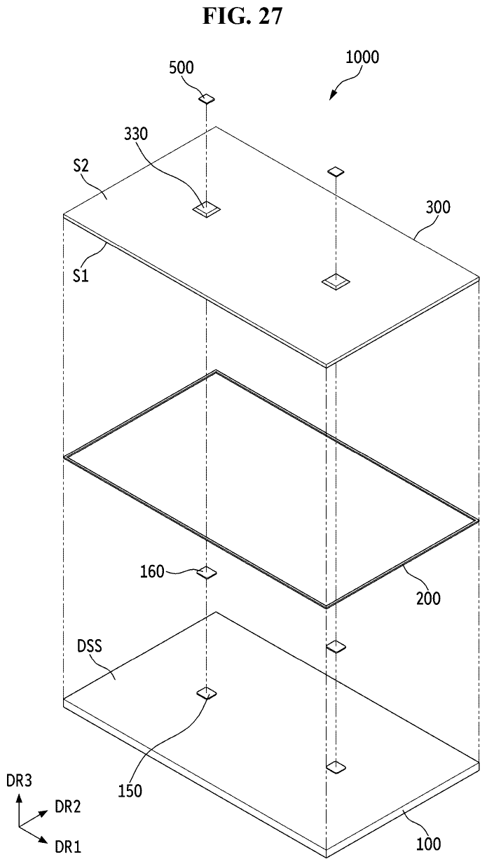

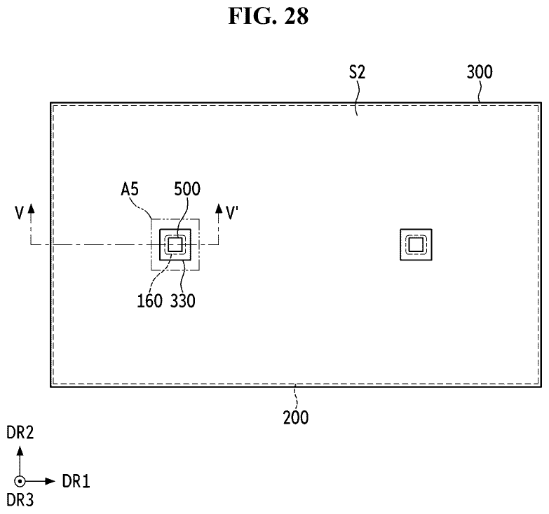

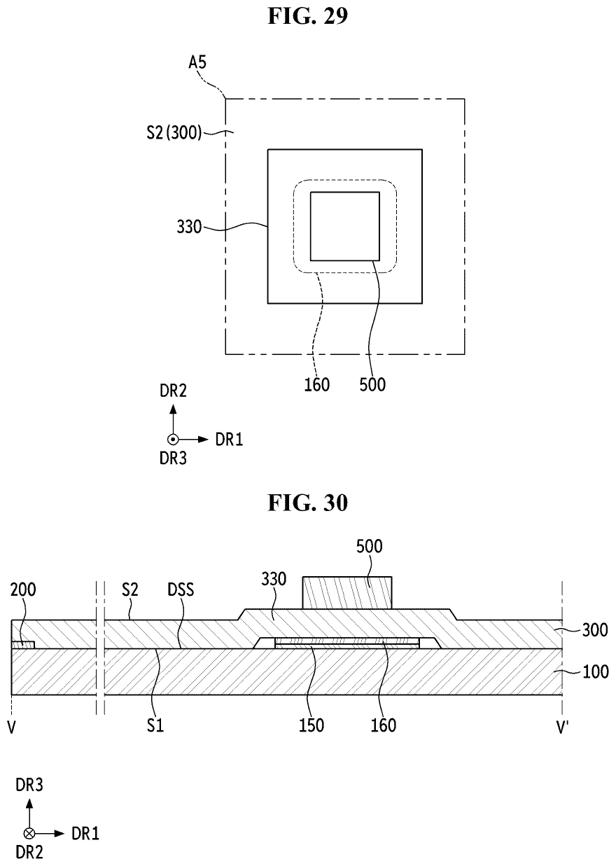

FIG. 27 is a perspective view of a display device 1000 according to an embodiment, FIG. 28 is a view of the display device 1000 of FIG. 27 viewed from an outer surface S2 of a cover 300, FIG. 29 is an enlarged view of area A5 of FIG. 28, and FIG. 30 is a cross-sectional view taken along line V-V′ of FIG. 28.

The display device 1000 of FIGS. 27 to 30 is substantially the same as the display device 1000 described above with reference to FIG. 23 except for a position of the magnet 500, and such a difference will be mainly described below.

In an embodiment, as illustrated in FIGS. 27 to 30, the magnet 500 may be disposed on the cover 300. In an embodiment, for example, the magnet 500 may be disposed on the outer surface S2 of the cover 300. Accordingly, the cover 300 may be disposed between the magnet 500 and the outer adhesive layer 200. In such an embodiment, the magnet 500 may be disposed on the cover 300 to overlap the connection layer 160. One surface of the magnet 500 may be in contact with the outer surface S2 of the cover 300. In an embodiment, for example, one surface of the magnet 500 may be attached to the outer surface S2 of the cover 300 by magnetic force from the magnet 500. The connection layer 160 may be pulled toward the cover 300 by the magnetic force from the magnet 500. Accordingly, adhesion force and coupling force between the cover 300 and the display panel 100 may be improved. Here, the connection layer 160 and the cover 300 may each include a metal material.

In an embodiment, as illustrated in FIG. 30, the connection layer 160 and the intermediate adhesive layer 150 may be disposed between the protrusion portion 330 of the cover 300 and the display panel 100.

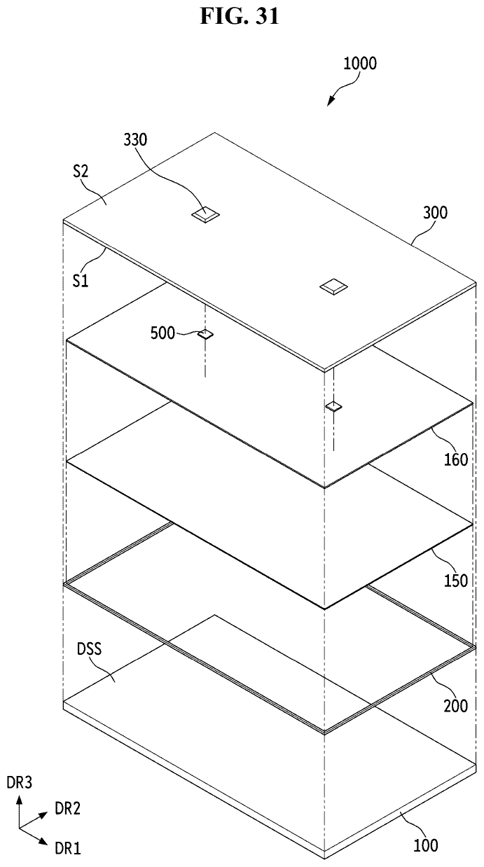

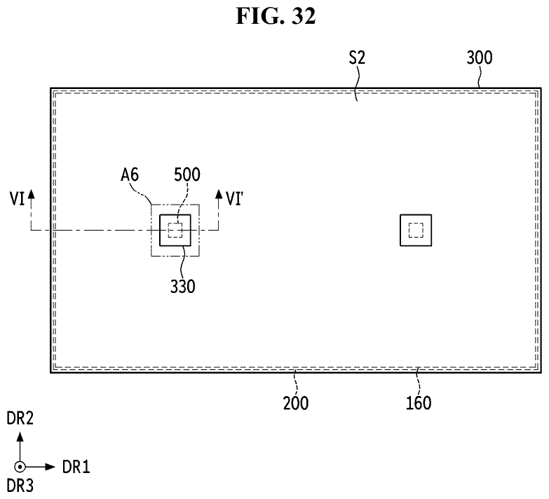

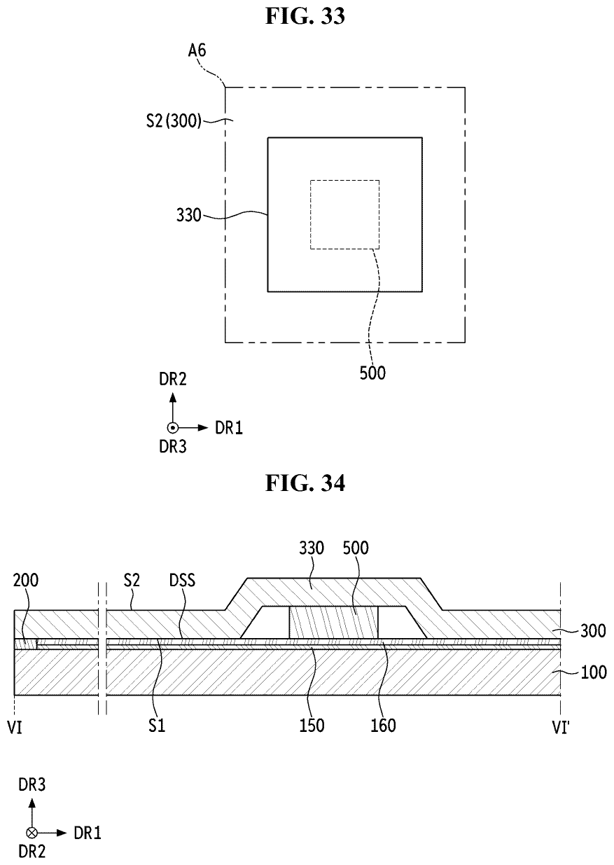

FIG. 31 is a perspective view of a display device 1000 according to an embodiment, FIG. 32 is a view of the display device 1000 of FIG. 31 viewed from an outer surface S2 of a cover 300, FIG. 33 is an enlarged view of area A6 of FIG. 32, and FIG. 34 is a cross-sectional view taken along line VI-VI′ of FIG. 32.

The display device 1000 of FIGS. 31 to 34 is substantially the same as the display device 1000 described above with reference to FIG. 23 except for shapes of the intermediate adhesive layer 150 and the connection layer 160, and such differences will be mainly described below.

In an embodiment, as illustrated in FIGS. 31 to 34, in a plan view, a size of the intermediate adhesive layer 150 may be greater than a size of the protrusion portion 330 of the cover 300. In an embodiment, for example, in a plan view, an edge of the intermediate adhesive layer 150 may surround the protrusion portion 330. In an embodiment, where the cover 300 of the display device 1000 includes a plurality of protrusion portions 330, in a plan view, the edge of the intermediate adhesive layer 150 may surround all of the plurality of protrusion portions 330.

In a plan view, the size of the intermediate adhesive layer 150 may be greater than a size of the magnet 500. In an embodiment, for example, in a plan view, the edge of the intermediate adhesive layer 150 may surround the magnet 500. In an embodiment, where the display device 1000 includes a plurality of magnets 500, in a plan view, the edge of the intermediate adhesive layer 150 may surround all of the plurality of magnets 500.

In a plan view, a size of the connection layer 160 may be greater than the size of the protrusion portion 330 of the cover 300. In an embodiment, for example, in a plan view, an edge of the connection layer 160 may surround the protrusion portion 330. In an embodiment, where the display device 1000 includes the plurality of protrusion portions 330, in a plan view, the edge of the connection layer 160 may surround all of the plurality of protrusion portions 330.

In a plan view, the size of the connection layer 160 may be greater than the size of the magnet 500. In an embodiment, for example, in a plan view, the edge of the connection layer 160 may surround the magnet 500. In an embodiment, where the display device 1000 includes the plurality of magnets 500, in a plan view, the edge of the connection layer 160 may surround all of the plurality of magnets 500.

In a plan view, the size of the connection layer 160 may be the same as the size of the intermediate adhesive layer 150, for example. The connection layer 160 may be disposed between the intermediate adhesive layer 150 and the cover 300.

In a plan view, the intermediate adhesive layer 150 and the connection layer 160 may be surrounded by the outer adhesive layer 200.

In an embodiment, as illustrated in FIG. 34, the magnet 500 may be disposed in an area surrounded by the protrusion portion 330 of the cover 300 and the connection layer 160.

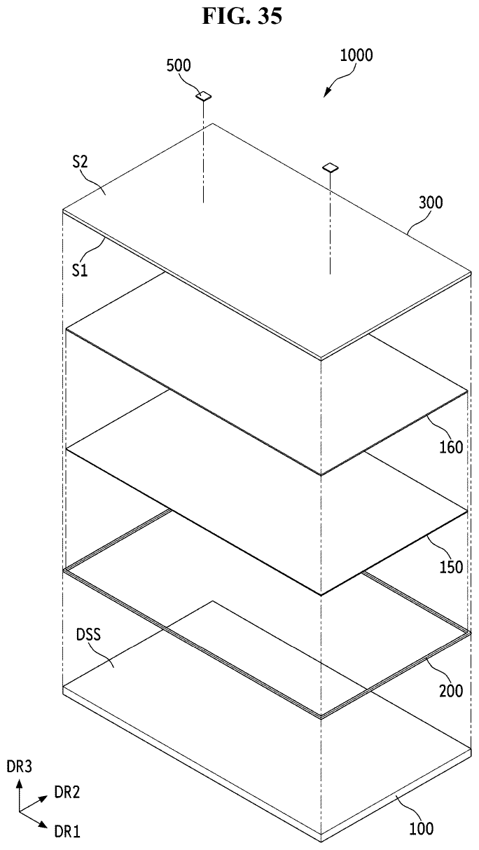

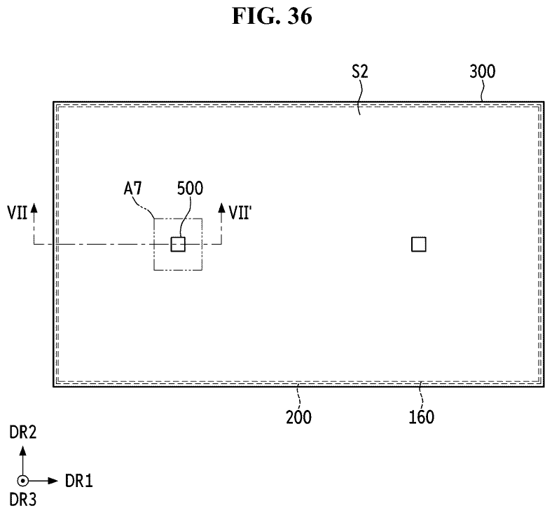

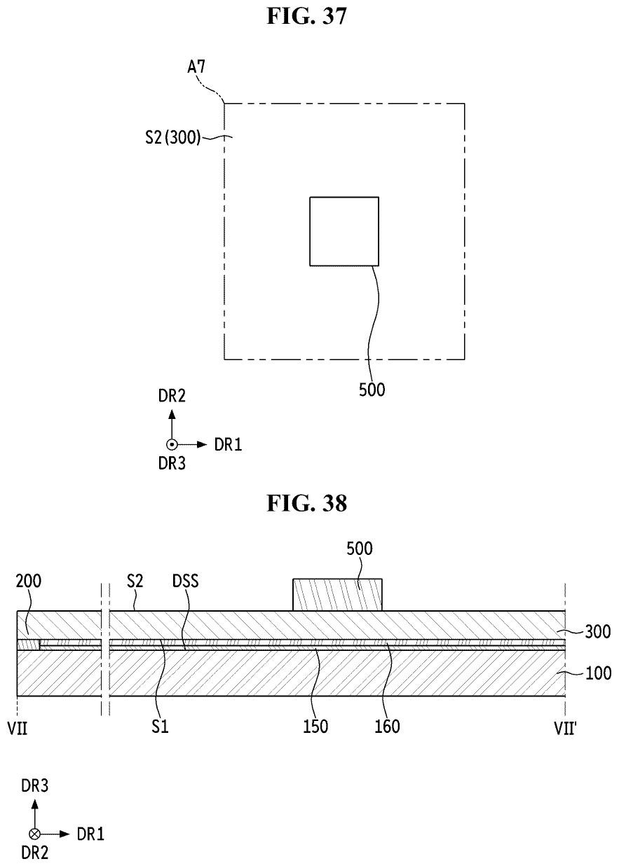

FIG. 35 is a perspective view of a display device 1000 according to an embodiment, FIG. 36 is a view of the display device 1000 of FIG. 35 viewed from an outer surface S2 of a cover 300, FIG. 37 is an enlarged view of area A7 of FIG. 36, and FIG. 38 is a cross-sectional view taken along line VII-VII′ of FIG. 36.

The display device 1000 of FIGS. 35 to 38 is substantially the same as the display device 1000 described above with reference to FIG. 31 except for a shape of the cover 300 and a position of the magnet 500, and such differences will be mainly described below.

In an embodiment, as illustrated in FIGS. 35 to 38, the magnet 500 may be disposed on the cover 300. In an embodiment, for example, the magnet 500 may be disposed on the outer surface S2 of the cover 300, which is flat.

In an embodiment, as illustrated in FIG. 38, the cover 300 may be disposed on the connection layer 160 and the outer adhesive layer 200 without a step.

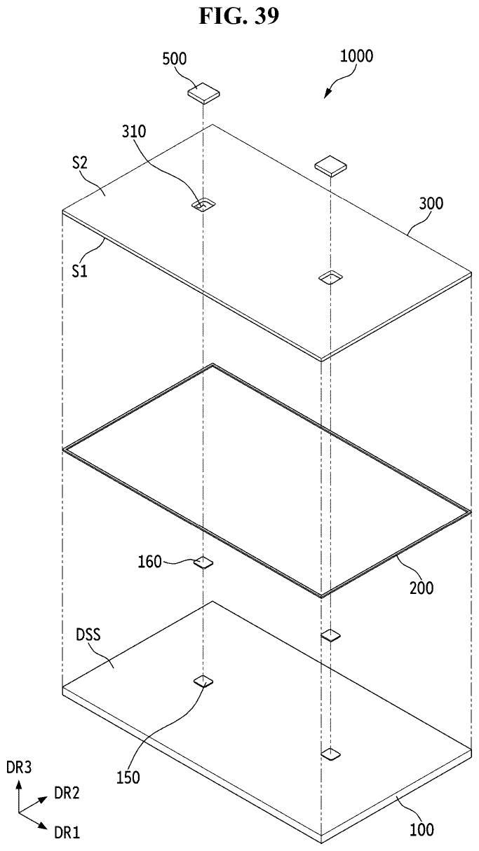

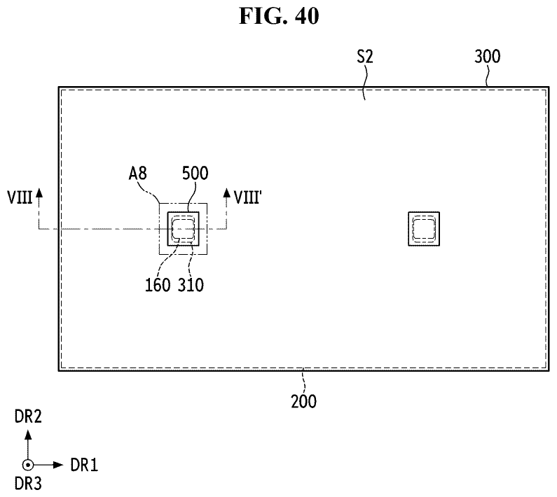

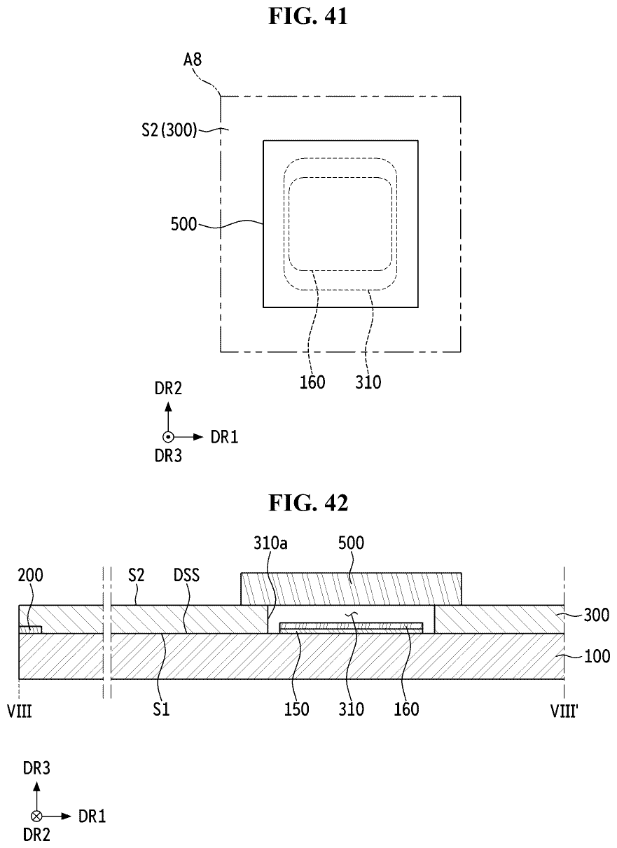

FIG. 39 is a perspective view of a display device 1000 according to an embodiment, FIG. 40 is a view of the display device 1000 of FIG. 39 viewed from an outer surface S2 of a cover 300, FIG. 41 is an enlarged view of area A8 of FIG. 40, and FIG. 42 is a cross-sectional view taken along line VIII-VIII′ of FIG. 40.

The display device 1000 of FIGS. 39 to 41 is substantially the same as the display device 1000 described above with reference to FIG. 27 except for a shape of the cover 300, and such a difference will be mainly described below.

In an embodiment, as illustrated in FIGS. 39 to 41, the cover 300 may be provided with a hole 310. The hole 310 may be defined of formed through the cover 300 in the thickness direction. In an embodiment, for example, the hole 310 may be defined through the cover 300 in the third direction DR3.

The magnet 500 may be disposed on the cover 300. In such an embodiment, the magnet 500 may be disposed to overlap the hole 310 of the cover 300.

In an embodiment, as illustrated in FIG. 41, in a plan view, a size of the magnet 500 may be greater than a size of the hole 310. In an embodiment, for example, in a plan view, an edge of the magnet 500 may surround the hole 310. The magnet 500 may be in contact with the outer surface S2 of the cover 300 positioned around the hole 310, on the hole 310. One surface of the magnet 500 may be attached to the outer surface S2 of the cover 300 by magnetic force from the magnet 500.

In an embodiment, as illustrated in FIG. 42, the magnet 500 may face the connection layer 160 through the hole 310. In an embodiment, for example, the magnet 500 and the connection layer 160 may face each other in the third direction DR3 through the hole 310. A gap may exist between the magnet 500 and the connection layer 160. The magnetic force from the magnet 500 may be provided to the connection layer 160 through the hole 310. The connection layer 160 may receive force pulling the connection layer 160 toward the magnet 500 by the magnetic force from the magnet 500. Accordingly, adhesion force and coupling force between the cover 300 and the display panel 100 may be improved.

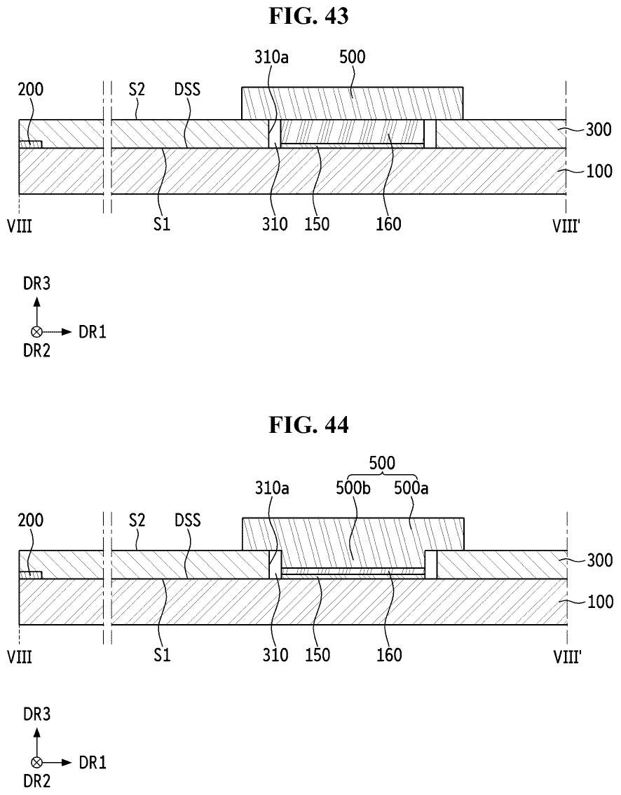

FIG. 43 is a cross-sectional view of another embodiment taken along line VIII-VIII′ of FIG. 40.

A display device 1000 of FIG. 43 is substantially the same as the display device 1000 described above with reference to FIG. 42 except for a shape of the connection layer 160, and such a difference will be mainly described below.

In an embodiment, as illustrated in FIG. 43, the connection layer 160 may be in contact with the magnet 500. In an embodiment, for example, the sum of a thickness of the connection layer 160 and a thickness of the intermediate adhesive layer 150 may be the same as or greater than a height of the inner wall 310a of the hole 310.

FIG. 44 is a cross-sectional view of another embodiment taken along line VIII-VIII′ of FIG. 40.

A display device 1000 of FIG. 44 is substantially the same as the display device 1000 described above with reference to FIG. 42 except for a shape of the magnet 500, and such a difference will be mainly described below.

In an embodiment, as illustrated in FIG. 44, the magnet 500 may include a first member 500a and a second member 500b. The first member 500a may be disposed on the cover 300. In an embodiment, for example, the first member 500a may be disposed on the outer surface S2 of the cover 300. The first member 500a is the same as the magnet 500 described above with reference to FIG. 39, and thus, any repetitive detailed description thereof will be omitted.

The second member 500b may extend from the first member 500a. In an embodiment, for example, the second member 500b may extend from the first member 500a toward the connection layer 160. The second member 500b may be disposed in the hole 310 of the cover 300. In an embodiment, for example, the second member 500b may be surrounded by the hole 310. The second member 500b may be in contact with the connection layer 160. One surface of the second member 500b may be attached to the connection layer 160 by magnetic force from the second member 500b. In a plan view, a size of the second member 500b may be smaller than a size of the first member 500a. The second member 500b and the first member 500a may be formed integrally with each other as a single unitary indivisible part.

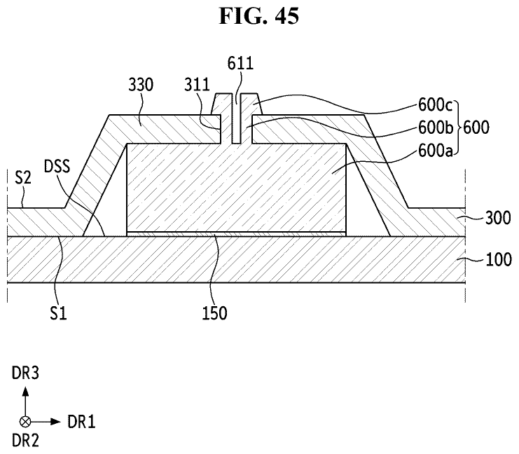

FIG. 45 is a cross-sectional view of a display device 1000 according to an embodiment.

The display device 1000 of FIG. 45 is substantially the same as the display device 1000 described above with reference to FIG. 26 except that the display device 1000 includes a connection member 600 instead of the connection layer 160 and the magnet 500 and except for a shape of the cover 300, and such differences will be mainly described below.

In an embodiment, as illustrated in FIG. 45, the cover 300 may include a protrusion portion 330. The protrusion portion 330 of FIG. 26 is substantially the same as the protrusion portion 330 of the cover 300 described above except that a hole 311 is defined therethrough.

The cover 300 may be provided with the hole 311 defined or formed through the protrusion portion 330. The hole 311 may be defined through the protrusion portion 330 of the cover 300 in the thickness direction of the protrusion portion 330. In an embodiment, for example, the hole 311 may be defined through the protrusion portion 330 in the third direction DR3.

In an embodiment, as illustrated in FIG. 45, the connection member 600 may include a base portion 600a, an extension portion 600b, and a fastening portion 600c. The base portion 600a, the extension portion 600b, and the fastening portion 600c may be formed integrally with each other. The connection member 600 including the base portion 600a, the extension portion 600b, and the fastening portion 600c may include, for example, a metal material or a plastic material.

The base portion 600a may be disposed between the intermediate adhesive layer 150 and the cover 300. In an embodiment, for example, the base portion 600a may be disposed between the intermediate adhesive layer 150 and the protrusion portion 330 of the cover 300. One surface of the base portion 600a may be in contact with the intermediate adhesive layer 150, and an opposing surface of the base portion 600a may be in contact with the protrusion portion 330.

The extension portion 600b may protrude from the base portion 600a. In an embodiment, for example, the extension portion 600b may protrude from the base portion 600a toward the hole 311 of the protrusion portion 330 in the third direction DR3. The extension portion 600b may be disposed in the hole 311 of the protrusion portion 330.

The fastening portion 600c may be disposed on the cover 300. In an embodiment, for example, the fastening portion 600c may be disposed on the outer surface S2 of the cover 300. The fastening portion 600c may be connected to the extension portion 600b through the hole 311 of the protrusion portion 330. A size of the fastening portion 600c may be greater than a size of the extension portion 600b. In an embodiment, for example, a size of the fastening portion 600c in the first direction DR1 may be greater than a size of the extension portion 600b in the first direction DR1. In other words, in a plan view, an edge of the fastening portion 600c may surround the extension portion 600b, a through hole 611, and the hole 311.

In a plan view, an edge of the base portion 600a may surround the fastening portion 600c, the extension portion 600b, the through hole 611, and the hole 311.

The through hole 611 defined through the fastening portion 600c and the extension portion 600b in the third direction DR3 may be disposed in the fastening portion 600c and the extension portion 600b. The size of the fastening portion 600c in the first direction DR1 and the size of the extension portion 600b in the first direction DR1 may be changed due to the through hole 611. When external force is not applied, the size of the extension portion 600b may be substantially the same as a size of the hole 311, and the size of the fastening portion 600c may be greater than the size of the hole 311. In an embodiment, for example, the extension portion 600b and the fastening portion 600c may contract by the external force, and may have elastic force so that their sizes are restored to their original sizes when the external force is removed.

When the external force is applied, the respective sizes of the extension portion 600b and the fastening portion 600c may become smaller than the size of the hole 311. Accordingly, the extension portion 600b and the fastening portion 600c may pass through the hole 311 in a state in which the external force is applied, and the sizes of the extension portion 600b and the fastening portion 600c may be restored to their original sizes when the external force applied to the extension portion 600b and the fastening portion 600c that pass through the hole 311 is removed. Accordingly, the connection member 600 may be fixed to the cover 300. Accordingly, adhesion force and coupling force between the cover 300 and the display panel 100 may be improved.

According to an embodiment, the cover 300 and the display panel 100 may be easily fixed to and disassembled from each other by the connection member 600.

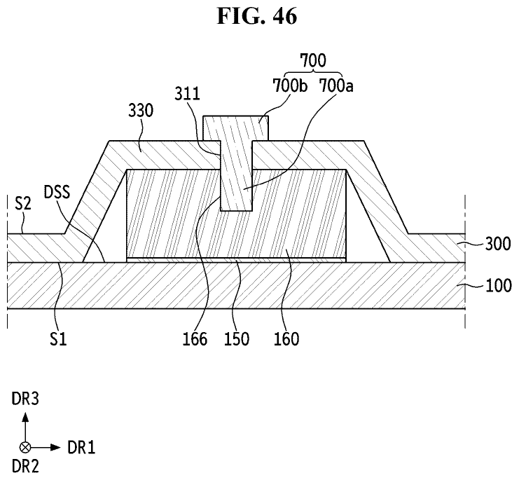

FIG. 46 is a cross-sectional view of a display device 1000 according to an embodiment.

The display device 1000 of FIG. 46 is substantially the same as the display device 1000 described above with reference to FIG. 26 except that the display device 1000 further includes a connection part 700 instead of the magnet 500 and except for a shape of the connection layer 160 and a shape of the cover 300, and such differences will be mainly described below.

In an embodiment, as illustrated in FIG. 46, the cover 300 may include a protrusion portion 330. The protrusion portion 330 of FIG. 26 is substantially the same as the protrusion portion 330 of the cover 300 described above except that a hole 311 is defined or formed therethrough.

The cover 300 may be provided with the hole 311 defined through the protrusion portion 330. The hole 311 may be defined through the protrusion portion 330 of the cover 300 in the thickness direction of the protrusion portion 330. In an embodiment, for example, the hole 311 may be defined through the protrusion portion 330 in the third direction DR3.

As illustrated in FIG. 46, the connection layer 160 may be disposed between the intermediate adhesive layer 150 and the cover 300. In an embodiment, for example, the connection layer 160 may be disposed between the intermediate adhesive layer 150 and the protrusion portion 330 of the cover 300. One surface of the connection layer 160 may be in contact with the intermediate adhesive layer 150, and an opposing surface of the connection layer 160 may be in contact with the protrusion portion 330. The connection layer 160 may have a groove 166 recessed in the third reverse direction. The groove 166 of the connection layer 160 may overlap the hole 311 of the cover 300. A screw thread may be disposed on an inner wall 310a of the groove 166 of the connection layer 160, for example. The connection layer 160 may include, for example, a metal material or a plastic material.

The connection part 700 may be disposed on the cover 300. In an embodiment, for example, the connection part 700 may be disposed on the outer surface S2 of the cover 300. The connection part 700 may be disposed through the hole 311 of the cover 300 and be inserted into the groove 166 of the connection layer 160. A size of the groove 166 in the first direction DR1 and a size of the hole 311 in the first direction DR1 may be the same as each other. In a plan view, an edge of the groove 166 and an edge of the hole 311 may overlap each other. The connection part 700 may include an extension portion 700a and a head portion 700b. The extension portion 700a and the head portion 700b may be formed integrally with each other as a single unitary indivisible part. The connection part 700 may be, for example, a screw bolt with a screw thread on an outer side thereof.

The extension portion 700a may be disposed in the groove 166 of the connection layer 160 and the hole 311 of the cover 300. A screw thread may be disposed or defined on an outer side of the extension portion 700a. The screw thread of the extension portion 700a may be coupled to the screw thread of the groove 166.

The head portion 700b may be disposed on the cover 300. In an embodiment, for example, the head portion 700b may be disposed on the outer surface S2 of the cover 300. The head portion 700b may be connected to the extension portion 700a. A size of the head portion 700b in the first direction DR1 may be greater than or the same as the size of the hole 311 in the first direction DR1 and the size of the groove 166 in the first direction DR1. In other words, in a plan view, an edge of the head portion 700b may surround the extension portion 700a and the hole 311.

In a plan view, an edge of the connection layer 160 may surround the head portion 700b, the extension portion 700a, and the hole 311.

Adhesion force and coupling force between the cover 300 and the display panel 100 may be further improved by the connection layer 160 and the connection part 700.

According to an embodiment, the cover 300 and the display panel 100 may be easily fixed to and disassembled from each other by the connection part 700 and the connection layer 160.

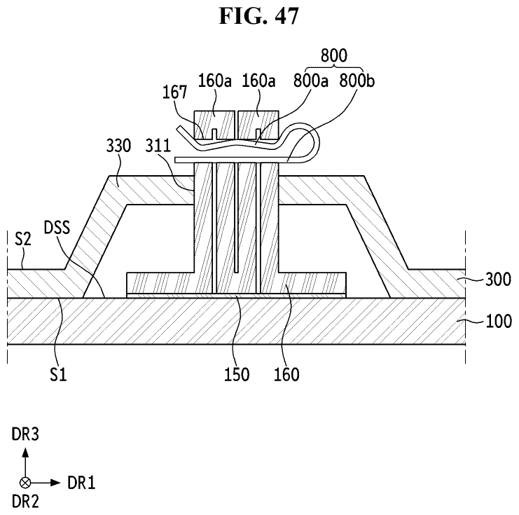

FIG. 47 is a cross-sectional view of a display device 1000 according to an embodiment.

The display device 1000 of FIG. 47 is substantially the same as the display device 1000 described above with reference to FIG. 26 except that the display device 1000 further includes a connection part 800 instead of the magnet 500 and except for a shape of the connection layer 160 and a shape of the cover 300, and such differences will be mainly described below.

In an embodiment, as illustrated in FIG. 47, the cover 300 may include a protrusion portion 330. The protrusion portion 330 of FIG. 26 is substantially the same as the protrusion portion 330 of the cover 300 described above except that a hole 311 is defined or formed therethrough.

The cover 300 may be provided with the hole 311 defined through the protrusion portion 330. The hole 311 may be defined through the protrusion portion 330 of the cover 300 in the thickness direction of the protrusion portion 330. In an embodiment, for example, the hole 311 may be defined through the protrusion portion 330 in the third direction DR3.

In an embodiment, as illustrated in FIG. 47, the connection layer 160 may be disposed on the intermediate adhesive layer 150. A portion of the connection layer 160 may extend onto the cover 300. In an embodiment, for example, the connection layer 160 may include a plurality of flexures 160a, and the flexures 160a may be exposed to the outside through the hole 311 of the cover 300. In other words, the flexures 160a may extend to the outside of the cover 300 through the hole 311 of the cover 300. One surface of the connection layer 160 may be in contact with the intermediate adhesive layer 150. In an embodiment, for example, one surface of the connection layer 160 may be attached to the intermediate adhesive layer 150. The connection layer 160 may include, for example, a metal material or a plastic material.

The connection part 800 may be disposed on the cover 300. In an embodiment, for example, the connection part 800 may be disposed on the outer surface S2 of the cover 300. The connection part 800 may be disposed through through holes 167 of the plurality of flexures 160a. In an embodiment, for example, the connection part 800 may be inserted into the through holes 167 of the flexures 160a in a direction crossing an extension direction (e.g., the third direction DR3) of the flexures 160a.

The connection part 800 may include a first fastening portion 800a and a second fastening portion 800b. The first fastening portion 800a and the second fastening portion 800b may be formed integrally with each other as single unitary indivisible part. One side of the first fastening portion 800a and one side of the second fastening portion 800b may be connected to each other. The connection part including one side of the first fastening portion 800a and the second fastening portion 800b may have a U shape. An interval between the first fastening portion 800a and the second fastening portion 800b may be changed by external force. In an embodiment, for example, the interval between the first fastening portion 800a and the second fastening portion 800b may be reduced by the external force, and the first fastening portion 800a and the second fastening portion 800b may have elastic force such that the interval is restored to an original interval when the external force described above is removed.

When the external force is applied, the interval between the first fastening portion 800a and the second fastening portion 800b may be reduced. Accordingly, in a state in which the external force is applied, the first fastening portion 800a and the second fastening portion 800b may pass through the through holes 167 of the flexures 160a, and when the external force applied to the first fastening portion 800a and the second fastening portion 800b passing through the through holes 167 of the flexures 160a is removed, the first fastening portion 800a and the second fastening portion 800b may become distant from each other so that the interval therebetween becomes the original interval. Accordingly, the connection layer 160 may be fixed to the cover 300. Accordingly, adhesion force and coupling force between the cover 300 and the display panel 100 may be improved.

According to an embodiment, the cover 300 and the display panel 100 may be easily fixed to and disassembled from each other by the connection part 800 and the connection layer 160.

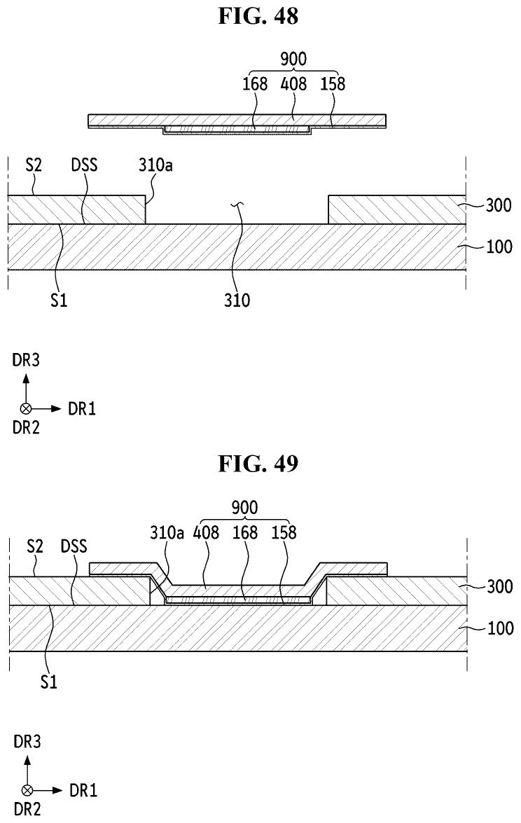

FIG. 48 is a cross-sectional view of a display device 1000 according to an embodiment, and FIG. 49 is a view illustrating a form in which an adhesive member 900 of FIG. 48 is attached to a cover 300 and a display panel 100.

According to an embodiment, as illustrated in FIGS. 48 and 49, the adhesive member 900 may be detachably connected to (or in contact with or attached to) the rear surface DSS of the display panel 100 and the cover 300.

In an embodiment, as illustrated in FIGS. 48 and 49, the adhesive member 900 may include a base layer 408, a connection layer 168, and an adhesive layer 158.

The base layer 408 may be disposed on the cover 300 and the hole 310 of the cover 300. The base layer 408 may include a flexible film. Alternatively, the base layer 408 may include an adhesive material on one surface thereof, and may include a bendable tape.

The connection layer 168 may be disposed on the base layer 408. In an embodiment, for example, the connection layer 168 may be disposed on the base layer 408 in the third reverse direction. In such an embodiment, the connection layer 168 may be disposed between the base layer 408 and the rear surface DSS of the display panel 100 within the hole 310 of the cover 300. The connection layer 168 may include a metal material. In an embodiment, for example, the connection layer 168 may be made of a material including at least one selected from stainless steel, aluminum (Al), copper (Cu), and graphite.

The adhesive layer 158 may be disposed on the connection layer 168 and the base layer 408. In an embodiment, for example, the adhesive layer 158 may be disposed on the connection layer 160 and the base layer 408 in the third reverse direction. Specifically, the adhesive layer 158 may be disposed between the rear surface DSS of the display panel 100 and the connection layer 168 and between the cover 300 and the base layer 408. The adhesive layer 158 may include, for example, a double-sided tape. One surface of the adhesive layer 158 may be in contact with the connection layer 160 and the base layer 408. In an embodiment, for example, one surface of the adhesive layer 158 may be attached to the connection layer 160 and the base layer 408.

In an embodiment, as illustrated in FIG. 49, the adhesive member 900 may be attached to the cover 300 and the display panel 100. In an embodiment, for example, an opposing surface of the adhesive layer 158 provided in the adhesive member 900 may be in contact with the cover 300. In addition, the adhesive layer 158 provided in the adhesive member 900 may be in contact with the rear surface DSS of the display panel 100 exposed through the hole 310 of the cover 300. In an embodiment, for example, an opposing surface of the adhesive layer 158 provided in the adhesive member 900 may be attached to the outer surface S2 of the cover 300 and the rear surface DSS of the display panel 100. In this case, the connection layer 168 may be disposed in the hole 310 of the cover 300.

The display device according to the embodiment can be applied to various electronic devices. The electronic device according to one embodiment includes the display device described above and may further include modules or devices having additional functions in addition to the display device.

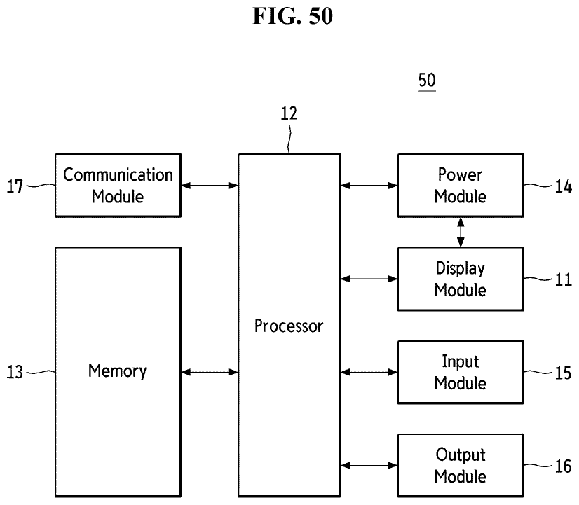

FIG. 50 is a block diagram of an electronic device according to one embodiment. Referring to FIG. 50, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

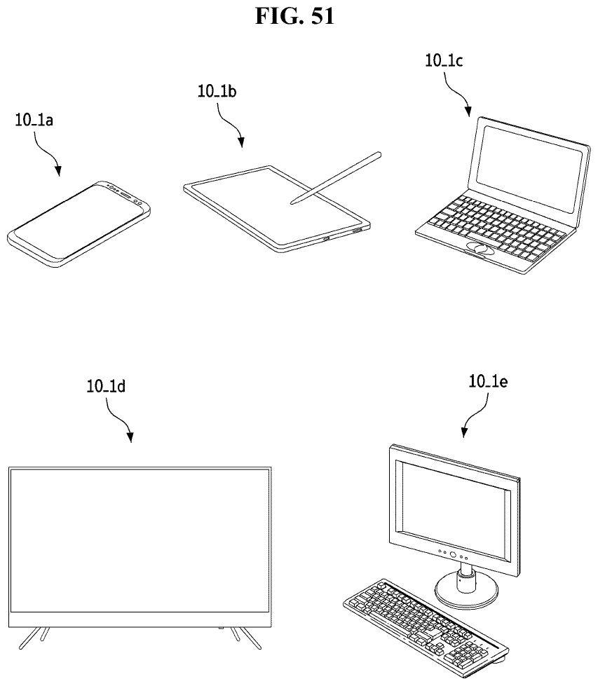

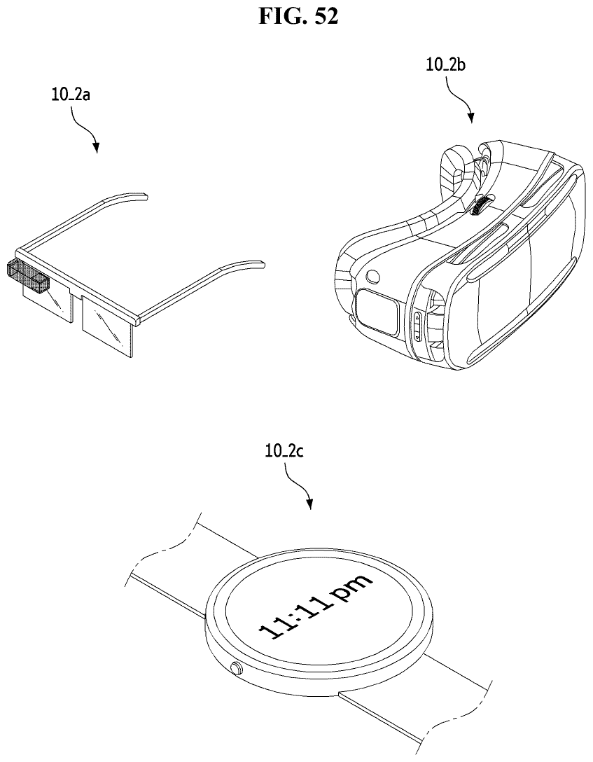

FIGS. 51, 52, and 53 are schematic diagrams of electronic devices according to various embodiments. FIGS. 51 to 53 illustrate examples of various electronic devices to which the display device according to the embodiments is applied.

FIG. 51 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

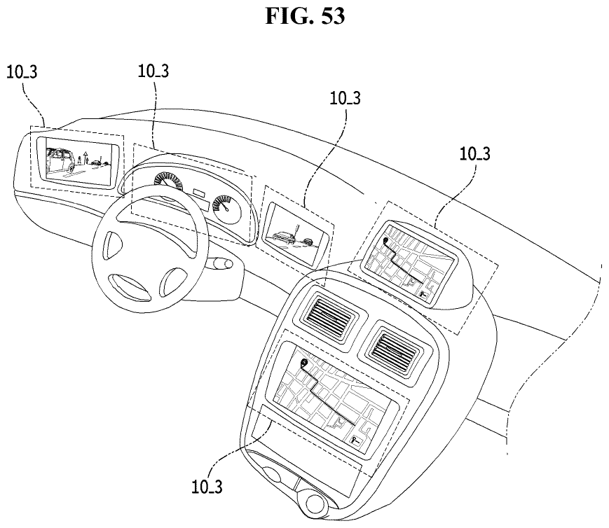

FIG. 52 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

The smart watch 10_2c includes a biometric sensor as an input device, and may provide biometric information recognized by the biometric sensor to the user through the display module. FIG. 53 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel including a front surface, on which a display area is defined, and a rear surface opposite to the front surface;
a connection layer disposed on the rear surface of the display panel;
a cover disposed on the connection layer, wherein a hole overlapping the connection layer is defined through the cover; and
a first adhesive layer disposed on the cover,
wherein the first adhesive layer is in contact with the cover, and in contact with the connection layer through the hole of the cover, and
the first adhesive layer is detachably connected to the cover and the connection layer.

2. The display device of claim 1, wherein the first adhesive layer includes a detachable tape.

3. The display device of claim 1, further comprising a second adhesive layer disposed between the rear surface of the display panel and the connection layer.

4. The display device of claim 1, further comprising a third adhesive layer disposed between an edge on the rear surface of the display panel and an edge of the cover.

5. The display device of claim 1, wherein in a plan view, the hole of the cover surrounds the connection layer.

6. The display device of claim 1, wherein the first adhesive layer is in contact with an outer surface of the cover positioned on a left side of the hole and an outer surface of the cover positioned on a right side of the hole in a plan view.

7. The display device of claim 1, wherein the first adhesive layer is in contact with an outer surface of the cover positioned on an upper side of the hole and an outer surface of the cover positioned on a lower side of the hole in a plan view.

8. The display device of claim 1, wherein the first adhesive layer is in contact with an outer surface of the cover positioned on a left side of the hole, an outer surface of the cover positioned on a right side of the hole, an outer surface of the cover positioned on an upper side of the hole, and an outer surface of the cover positioned on a lower side of the hole.

9. The display device of claim 1, wherein in a plan view, an edge of the first adhesive layer surrounds the hole and the connection layer.

10. The display device of claim 1, wherein an inner wall of the hole of the cover has a curved portion.

11. The display device of claim 10, wherein the inner wall of the hole of the cover has the curved portion in an area in contact with the first adhesive layer.

12. The display device of claim 1, wherein the hole of the cover has a size which gradually decreases along a direction toward the display panel.

13. The display device of claim 1, wherein in a plan view, an edge of the connection layer surrounds the hole.

14. The display device of claim 13, further comprising a third adhesive layer disposed between the edge of the connection layer and an edge of the cover.

15. A display device comprising:
a display panel including a front surface, on which a display area is defined, and a rear surface opposite to the front surface;
a connection layer disposed on the rear surface of the display panel;
a cover disposed on the connection layer and including a protrusion portion overlapping the connection layer; and
a magnet disposed between the connection layer and the protrusion portion of the cover,
wherein the magnet is in contact with the protrusion portion of the cover and the connection layer, and
the magnet is detachably connected to the cover and the connection layer.

16. The display device of claim 15, wherein in a plan view, an edge of the connection layer surrounds the magnet.

17. The display device of claim 15, wherein in a plan view, an edge of the protrusion portion surrounds the connection layer and the magnet.

18. A display device comprising:
a display panel including a front surface, on which a display area is defined, and a rear surface opposite to the front surface;
a connection layer disposed on the rear surface of the display panel;
a cover disposed on the connection layer and including a protrusion portion overlapping the connection layer; and
a magnet disposed on the protrusion portion of the cover to overlap the connection layer,
wherein the magnet is in contact with the protrusion portion of the cover, and
the magnet is detachably connected to the cover.

19. The display device of claim 18, wherein in a plan view, an edge of the connection layer surrounds the magnet.

20. A display device comprising:
a display panel including a front surface, on which a display area is defined, and a rear surface opposite to the front surface;
a connection layer disposed on the rear surface of the display panel;
a cover disposed on the connection layer, wherein a hole overlapping the connection layer is defined through the cover; and
a magnet disposed on the cover,
wherein the magnet is in contact with the cover, and in contact with the connection layer through the hole of the cover, and
the magnet is detachably connected to the cover and the connection layer.

21. The display device of claim 20, wherein in a plan view, an edge of the magnet surrounds the hole of the cover and the connection layer.

22. The display device of claim 20, wherein the magnet and the connection layer are in contact with each other.

23. The display device of claim 22, wherein the magnet includes:
a first member disposed on the cover; and
a second member extending from the first member toward the connection layer and in contact with the connection layer within the hole of the cover.

24. A display device comprising:
a display panel including a front surface, on which a display area is defined, and a rear surface opposite to the front surface;
a cover disposed on the rear surface of the display panel, wherein a hole is defined through the cover; and
a connection member disposed between the display panel and the cover,
wherein the connection member includes:
a base portion disposed between the display panel and the cover;
an extension portion extending from the base portion and inserted into the hole of the cover; and
a fastening portion disposed on the cover to overlap the hole and connected to the extension portion.

25. The display device of claim 24, wherein a through hole is defined through the extension portion and the fastening portion.

26. The display device of claim 24, further comprising an adhesive layer disposed between the rear surface of the display panel and the base portion.

27. A display device comprising:
a display panel including a front surface, on which a display area is defined, and a rear surface opposite to the front surface;
a cover disposed on the rear surface of the display panel, wherein a hole is defined through the cover;
a connection layer disposed between the display panel and the cover and including a groove overlapping the hole of the cover; and
a connection part disposed through the hole of the cover and inserted into the groove of the connection layer.

28. The display device of claim 27, wherein the connection part includes:
an extension portion inserted into the hole and the groove; and
a head portion disposed on the cover to overlap the hole and connected to the extension portion.

29. A display device comprising:
a display panel including a front surface, on which a display area is defined, and a rear surface opposite to the front surface;
a cover disposed on the rear surface of the display panel, wherein a hole is defined through the cover;
a connection layer disposed between the display panel and the cover and including a plurality of flexures extending to an outside of the cover through the hole of the cover; and
a connection part inserted into through holes of the plurality of flexures in a direction crossing an extension direction of the plurality of flexures.

30. A display device comprising:
a display panel including a front surface on which a display area is disposed and a rear surface disposed on a side opposite to the front surface;
a cover disposed on the rear surface of the display panel, wherein a hole is defined through the cover; and
an adhesive member disposed on the cover to overlap the hole of the cover,
wherein the adhesive member includes:
a base layer disposed on the cover and the hole;
a connection layer disposed between the rear surface of the display panel and the base layer within the hole; and
an adhesive layer disposed between the rear surface of the display panel and the connection layer and between the cover and the base layer.

31. The display device of claim 30, wherein the adhesive member is detachably connected to the rear surface of the display panel and the cover.

32. An electronic device comprising:
a processor;
a memory; and
a display device,
wherein the display device includes:
a display panel including a front surface, on which a display area is defined, and a rear surface opposite to the front surface;
a connection layer disposed on the rear surface of the display panel;
a cover disposed on the connection layer, wherein a hole overlapping the connection layer is defined through the cover; and
a first adhesive layer disposed on the cover,
wherein the first adhesive layer is in contact with the cover, and in contact with the connection layer through the hole of the cover, and
the first adhesive layer is detachably connected to the cover and the connection layer.

33. The electronic device of claim 32, wherein the first adhesive layer includes a detachable tape.

34. The electronic device of claim 32, further comprising a second adhesive layer disposed between the rear surface of the display panel and the connection layer.

35. The electronic device of claim 32, further comprising a third adhesive layer disposed between an edge on the rear surface of the display panel and an edge of the cover.
